(19) United States
(12) Patent Application Publication
(10) Pub. No.: US 2015/0039391 A1
(43) Pub. Date: Feb. 5, 2015

(54) ESTIMATION AND MANAGEMENT OF LOADS IN ELECTRIC VEHICLE NETWORKS

(71) Applicants: Barak Hershkovitz, Even Yehuda (IL); Motty Cohen, Kiryat Motzkin (IL); Emek Sadot, Moshav Ram On (IL); Yaron Straschnov, Kadima (IL)

(72) Inventors: Barak Hershkovitz, Even Yehuda (IL); Motty Cohen, Kiryat Motzkin (IL); Emek Sadot, Moshav Ram On (IL); Yaron Straschnov, Kadima (IL)

(73) Assignee: BETTER PLACE GMBH, Zug (CH)

(21) Appl. No.: 14/238,709

(22) PCT Filed: Aug. 15, 2012
(86) PCT No.: PCT/IL2012/050313

§ 371 Date: Jul. 31, 2014

Related U.S. Application Data
(60) Provisional application No. 61/524,288, filed on Aug. 16, 2011.
(60) Provisional application No. 61/524,297, filed on Aug. 16, 2011.

(51) Int. Cl. G06Q 30/02; G01R 21/00; G01R 31/36

(52) U.S. Cl. CPC G06Q 30/0202; G01R 31/3606; G01R 21/00
USPC 705/7.31

(57) ABSTRACT

Methods and systems are presented for predicting demand for battery services in an electric vehicle network. The predicted demand may be used for managing the electric vehicle network, for example, by adjusting battery policies in order to provide improved battery services to users of electric vehicles. The battery policies can be adjusted by increasing or decreasing battery charging rates within the electric vehicle network, and recommending alternative battery service locations to users of vehicles who might otherwise choose a congested battery service location.

### TECHNOLOGICAL FIELD

The present disclosure relates generally to estimation of loads in electric vehicle networks and to possible load management approaches relying on such estimations.

### BACKGROUND

Vehicles (e.g., cars, trucks, planes, boats, motorcycles, autonomous vehicles, robots, forklift trucks, etc.) are an integral part of the modern economy. Unfortunately, fossil fuels, like oil which is typically used to power such vehicles, have numerous drawbacks including: dependence on limited sources of fossil fuels; the sources are often in volatile geographic locations; and such fuels produce pollutants and likely contribute to climate change. One way to address these problems is to increase the fuel efficiency of these vehicles.

Recently, gasoline-electric hybrid vehicles have been introduced, which consume substantially less fuel than their traditional internal combustion counterparts, i.e., they have better fuel efficiency. Fully-electric vehicles are also gaining popularity. Batteries play a critical role in the operation of such hybrid and fully-electric vehicles. However, present battery technology does not provide an energy density comparable to gasoline. On a typical fully charged electric vehicle battery, the electric vehicle may only be able to travel up to 40 miles before needing to be recharged. Therefore, in order for a vehicle to travel beyond the single-charge travel range, the spent battery needs to be charged or exchanged with a fully-charged battery.

Providing a network of battery service stations for charging and/or exchanging batteries of electric vehicles helps ensure that drivers of electric vehicles are able to acquire additional energy for their vehicles when needed. The amount of energy required by the overall network, however, will not necessarily be steady or consistent, and the electricity demands of the battery service stations will thus rise and fall with the aggregated demand of the electric vehicles. Such varying demands often result in unpredictable electrical loads and higher overall energy costs, and can be detrimental to both power suppliers and operators of electric vehicle networks. As such, a need exists for an easy and efficient way to predict and manage the demand for electrical energy within an electric vehicle network.

### GENERAL DESCRIPTION

There is a need in the art for a novel method and system for managing an electric vehicle network, capable of predicting a demand at one or more battery service stations, or within a geographic area, and generating data indicative thereof. It is also a need that the control center is capable of estimating a minimum and maximum charging load of the electric vehicle network and generating data indicative thereof. Based on the generated data, the control center system may then adjust the actual charging load of the electric vehicle network. For example, the control center system may adjust the actual charging load of the electric vehicle network to be between the estimated minimum and the maximum charging loads by adjusting one or more battery policies.

Optionally, the actual charging load can be adjusted in accordance with certain predefined factors. To this end, systems and methods are provided for predicting demand and managing loads in a flexible electric vehicle network, and for adjusting battery policies in response to the predicted demand. Some of the embodiments disclosed herein provide computer-implemented methods of managing an electric vehicle network. These methods may be performed by a computer system having one or more processors and memory storing one or more programs for execution by the one or more processors.

In one exemplary embodiment the methods may include receiving battery charge status data and location data from each of a plurality of electric vehicles, and estimating the load based on the received data. For example, the received data may be used for determining an estimated minimum charging load at least partially based on an amount of additional energy required by the batteries of the electric vehicles to allow each of the electric vehicles to proceed to its respective final destination (e.g., intended destinations selected by users). In some embodiments, the minimum charging load is based on the final destination, current location data, and battery status data of each respective electric vehicle. In some embodiments, final destinations are predicted (e.g., based on one or more prediction parameters). The battery status data may comprise one or more of the following data: the battery charge level, the battery temperature, battery health, battery charge history, battery age, battery efficiency, and suchlike.

The method may include determining, for each respective electric vehicle, a likely battery service station (i.e. the battery service station where a vehicle might receive battery related services) and a likely vehicle arrival time at such battery service station. For example, this determination may be based at least partially on the location, final destination, and the battery charge status for each of the electric vehicles. In some embodiments, the determination is further based on the speed of the vehicle, speed limits, traffic conditions, and/or the average speed of a group of other vehicles in proximity to the respective electric vehicle.

In some possible embodiments the method includes predicting demand at one or more battery service stations based at least partially on the likely battery service station. The demand prediction may further utilize the likely vehicle arrival time for each of the electric vehicles. In some embodiments, the method includes predicting demand in one or more geographic areas based at least partially on the likely battery service station and the likely vehicle arrival time for each of the electric vehicles. In some embodiments, the method also includes predicting a congestion point based on the predicted demand at the one or more battery service stations, and possibly also determining whether to adjust one or more battery policies responsive to the predicted demand.

Some of the methods may also include determining an estimated maximum charging load that the batteries of the electric vehicles can place on a power grid. For example, the maximum charging load may be at least partially based on an estimated load placed on the power grid if substantially all of the electric vehicles likely to be coupled to the power grid at a certain time were to be simultaneously charged at a maximum rate.

Exemplary methods may include adjusting one or more battery policies of the batteries of the electric vehicles to adjust an actual charging load of the electric vehicle network between the estimated minimum charging load and the estimated maximum charging load based on certain predetermined factors. In some embodiments, the actual charging load is adjusted in accordance with the price of electricity. In some embodiments, the actual charging load is adjusted in accordance with a predicted future energy demand.

In some embodiments, adjusting battery policies includes increasing or decreasing a charge rate of at least one replacement battery coupled to the power grid (e.g., electric vehicle network) at one or more battery service stations, and/or a charge rate of at least one of the electric vehicles coupled to the power grid. In some embodiments, adjusting battery policies includes recommending an alternative battery service station, or a battery exchange instead of a battery charge, to a user of the respective electric vehicle. In some embodiments, adjusting the one or more battery policies includes increasing or decreasing the number of available replacement batteries at one or more of the battery service stations.

In some embodiments, the method further includes providing (displaying) a map illustrating a geographic area having a plurality of battery service stations, and displaying on the map one or more graphical representations indicating a respective demand for one or more of the battery service stations in the illustrated geographic area.

In some embodiments, the method further includes representing the estimated minimum charging load and the estimated maximum charging load as a set of data pieces/points representing energy quantities over a predefined time. In some embodiments, the method further includes fitting at least a subset of the data points to a curve function. In some embodiments, the method includes displaying, on a display device, a graph containing at least a subset of the data points.

In one aspect the present application provides a method of managing an electric vehicle network, comprising receiving battery status data and vehicle location data from each of a plurality of electric vehicles, utilizing the received battery status data and vehicle location data and data about a final destination for each of the electric vehicles, and determining for each respective electric vehicle battery service data including a likely battery service station, and predicting demand at one or more battery service stations based on at least the determined likely battery service station for each of the electric vehicles. The predicted demand may be used to manage consumption loads on the electric vehicle network. For example, the predicted demand may be used to determine whether to adjust one or more battery policies of one or more battery service station on the vehicle electric network.

In some embodiments the determined battery service data includes a likely vehicle arrival time expressing estimation of arrival time of the respective electric vehicle at the likely battery service station. The likely vehicle arrival times determined for the vehicles may be also used in the prediction of the demand, together with the determined likely battery service stations. For example, the likely vehicle arrival time may be used to refine the predicted demand to show the predicted demand at specific time points and/or during one or more time intervals.

The method may further comprise estimating a minimum charging load at least partially based on an amount of additional energy required by the batteries of the electric vehicles to allow each of the electric vehicles to proceed to its respective final destination, and estimating a maximum charging load that the batteries of the electric vehicles can place on a power grid (e.g., based the respective battery status data of each of the electric vehicles). In possible embodiments the predicted demand is adjusted at least partially based on the estimated minimum charging load and the estimated maximum charging load.

In possible embodiment the estimation of the minimum charging load is determined at least partially based on actual energy demand of the electric vehicle network determined over a predetermined time window based at least partially on data received from the vehicles and/or the battery service stations. Alternatively, estimated minimum charging load may be a sum of estimated minimum individual charging loads placed on the power grid by each respective electric vehicle.

The estimated maximum charging load may be based at least partially on an estimated load placed on the power grid if all of the vehicles coupled to the power grid at a certain time were to be simultaneously charged at a maximum rate.

The determination of whether to adjust one or more battery policies may include determining a supply of battery services at the one or more battery service stations, and comparing the predicted demand at the one or more battery service stations and the supply of battery services at the one or more battery service stations.

Optionally, the one or more battery policies are adjusted based on the demand predicted at the one or more battery service stations. Alternatively, the one or more battery policies are adjusted based on the comparison between the predicted demand at the one or more battery service stations and the supply of battery services at the one or more battery service stations.

In some embodiments determining the final destination comprises receiving respective final destinations from at least a subset of the plurality of electric vehicles. Alternatively or additionally, the respective final destinations may be intended destinations for some users of the subset of electric vehicles.

According to a possible embodiment, determining the final destination comprises predicting the final destination of a respective electric vehicle when an operator of the respective electric vehicle has not selected an intended final destination. For example, the predicted final destination may be selected from of the following: a home location; a work location; a battery service station; a previously visited location; and a frequently visited location.

In some embodiments the one or more battery service stations are selected from the following: charge stations for recharging the batteries of the electric vehicles; and battery exchange stations for replacing the batteries of the electric vehicles.

The adjustment of the one or more battery policies may comprise increasing or decreasing a charge rate of: at least one replacement battery (i.e. stored at the battery service station) coupled to the electric vehicle network at a battery service station; or of a battery of at least one of the electric vehicles coupled to the electric vehicle network when receiving services at a battery service station. Optionally, the adjustment of the one or more battery policies comprises recommending an alternate battery service station to a user of a respective electric vehicle, and/or changing a number of available replacement batteries at one or more of the battery service stations.

The method may further comprise informing a utility provider about an expected power demand based at least partially on the predicted demand at the one or more battery service stations.

In possible embodiments determining the respective likely battery service station and the respective likely vehicle arrival time for a respective electric vehicle is further based on a speed of the respective electric vehicle.

The method may further comprise increasing the demand predicted at the one or more battery service stations to account for demand from one or more electric vehicles of a second plurality of electric vehicles. For example, the second plurality of vehicles may include vehicles that are not in communication with the computer system.

According to some embodiments a displaying step is used to display on a display device a map illustrating a geographic area having a plurality of battery service stations and one or more graphical representations indicating a respective demand for one or more of the battery service stations in the illustrated geographic area.

In another aspect the present application provides a system for managing an electric vehicle network. The system may comprise a communication module for exchanging data with one or more battery service stations and with a plurality of electric vehicles (i.e. a computer system of the vehicle and/or a user's mobile phone at the vehicle), one or more data processors, and memory storing data and one or more software programs for execution by the one or more processors. The data and the one or more programs stored in the memory may include a battery status module configured to determine a battery charge status based on battery status data received from each of the plurality of electric vehicles, a vehicle location database for maintaining location data received from the vehicles, and a demand prediction module. The demand prediction module is configured and operable to identify a final destination for each of the electric vehicles (e.g., based on data received from the vehicles and/or at least partially on the location data, the final destination, and/or the battery charge status), determine for each respective electric vehicle a location of a likely battery service station; and predict demand at one or more battery service stations based at least partially on the likely battery service location for each respective electric vehicle.

The system may comprise one or more of the following:
a battery service station module configured and operable to receive and maintain station status data received from the battery service stations;
a battery policy module configured and operable to determine whether to adjust one or more battery policies based at least on one of the predicted demand and the station status data; and/or
a map module configured and operable to generate and/or display on a map, displayed in a display device, a graphical representation indicating a respective demand for battery services in one or more geographic areas.

According to yet another aspect, there is provided a method of managing an electric vehicle network comprising a plurality of electric vehicles, the method comprising estimating a minimum charging load a power grid of the electric vehicle network at least partially based on an amount of additional energy required by batteries of the electric vehicles to allow each of the electric vehicles to proceed to its respective final destination, estimating a maximum charging load that the batteries of the electric vehicles can place on the power grid, and adjusting one or more battery policies of the battery service stations of the electric vehicles to adjust an actual charging load of the power grid between the estimated minimum charging load and the estimated maximum charging load based on certain predetermined factors.

The estimating of the minimum and/or maximum charging load may be carried out utilizing any of the techniques described hereinabove or hereinbelow.

Optionally, the one or more battery policies are adjusted at least partially based on a price of energy from the power grid.

The batteries of the electric vehicles typically have an existing charge level, such that the amount of additional energy required by the batteries of the electric vehicles is an amount of energy in addition to an aggregation of the existing charge level. Optionally, each respective electric vehicle may have an associated minimum battery charge level that is determined by one or more service agreements with an owner or an operator of the respective vehicle.

The method may further comprise sending to a utility provider the estimated minimum charging load and the estimated maximum charging load, and receiving from the utility provider an energy plan comprising preferred charging loads for a predetermined time window. In this way, the one or more battery policies may be adjusted in accordance with the energy plan.

In some embodiments, whenever the battery of a respective electric vehicle contains more energy than necessary for the respective electric vehicle to reach its final destination, said battery is capable of providing energy to the power grid.

The adjusting of the one or more charging policies may comprise increasing or decreasing a charge rate of at least one of the replacement batteries coupled to the power grid; and/or at least one electric vehicle coupled to the power grid. In some cases the charge rate may be of negative value.

According to some embodiments the electric vehicle network includes one or more storage batteries coupled to the power grid. In this way, the adjusting of the one or more battery policies may comprise increasing or decreasing a charge rate of at least one of the storage batteries.

As indicated above the estimated minimum charging load and the estimated maximum charging load may be represented by a set of data points representing energy quantities over a predefined time. This presentation may be utilized for fitting at least a subset of the set of data points to a curve function, or alternatively/additionally displaying, on a display device, a graph containing at least a subset of the set of data points.

In a possible embodiment the one or more battery policies are adjusted in order to minimize energy costs of the electric vehicle network over a predetermined time window.

### BRIEF DESCRIPTION OF THE DRAWINGS

In order to understand the invention and to see how it may be carried out in practice, embodiments will now be described, by way of non-limiting example only, with reference to the accompanying drawings, in which like reference numerals are used to indicate corresponding parts, and in which:

FIG. 1 illustrates an electric vehicle network;

FIG. 2 is a block diagram illustrating components of a vehicle, according to some embodiments;

FIG. 3 is a block diagram illustrating components of a control center system, according to some embodiments;

FIG. 4 is a flow diagram illustrating a method of managing an electric vehicle network, according to some embodiments;

FIG. 5 is a flow diagram illustrating another method of managing an electric vehicle network, according to other embodiments;

FIG. 6 illustrates a map for displaying demand data, according to some embodiments;

FIG. 7 illustrates a map for displaying demand data, according to other embodiments;

FIG. 8 illustrates a map for displaying demand data, according to other embodiments;

FIG. 9 is a flow diagram illustrating a method for managing an electric vehicle network, according to some embodiments;

FIG. 10A illustrates a graph displaying estimated minimum and estimated maximum charging curves, according to some embodiments;

FIG. 10B illustrates another graph displaying estimated minimum and estimated maximum charging curves, according to some embodiments;

FIG. 11 schematically illustrates a vehicle data record used in the load estimation process according to some embodiments;

FIG. 12 schematically illustrates a demand table predicted for a specific battery service station; and

FIG. 13 is a flowchart demonstrating a process for adjusting the actual charging rate of a vehicle network according to electricity price and the minimum/maximum charging loads of the network.

### DETAILED DESCRIPTION OF EMBODIMENTS

The following is a detailed description of methods and systems for predicting and displaying demand data for battery service stations and/or an electric vehicle network. Reference will be made to certain embodiments of the invention, examples of which are illustrated in the accompanying drawings.

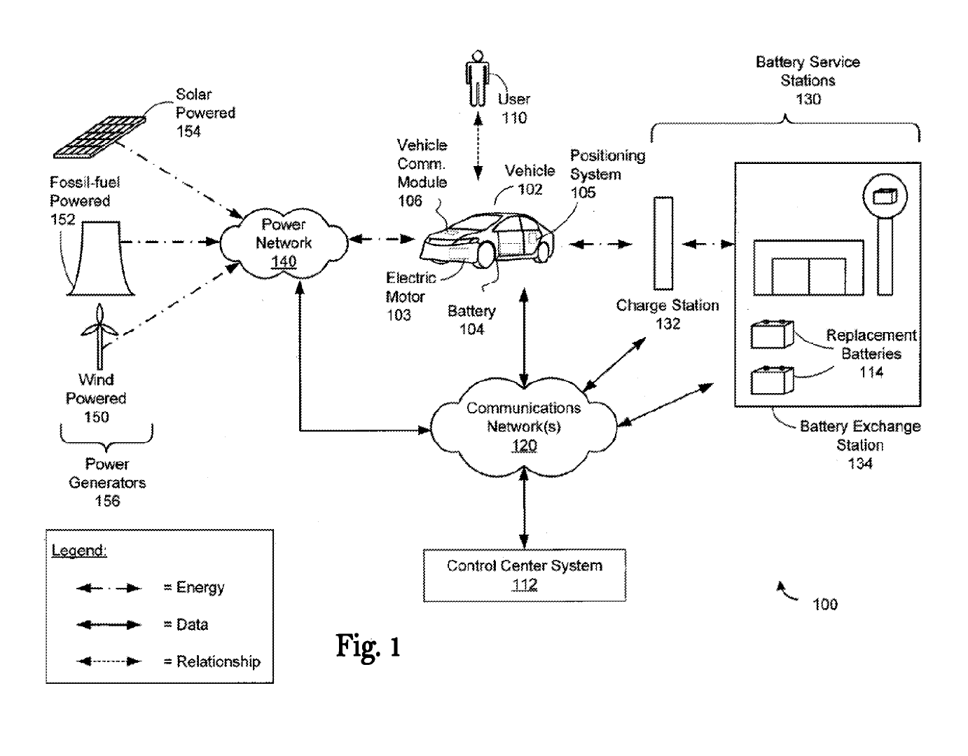

FIG. 1 is a block diagram of an electric vehicle network 100, according to some embodiments. As exemplified in FIG. 1, the electric vehicle network 100 includes at least one electric vehicle 102 having one or more electric motors 103, one or more batteries 104 (each including one or more batteries or battery cells), a positioning system 105, a communication module 106, and any combination of the aforementioned components.

In some embodiments, the one or more electric motors 103 drive one or more wheels of the electric vehicle 102. In these embodiments, the one or more electric motors 103 receive energy from one or more batteries 104 that are electrically and mechanically attached to the electric vehicle 102. The one or more batteries 104 of the electric vehicle 102 may be charged at a home of a user 110. Alternatively, the one or more batteries 104 may be serviced (e.g., exchanged and/or charged, etc.) at a battery service station 130 within the electric vehicle network 100. The battery service stations 130 may include charge stations 132 for charging the one or more batteries 104, and/or battery exchange stations 134 for exchanging the one or more batteries 104. Battery service stations are described in greater detail in U.S. Pat. No. 8,006,793, which is hereby incorporated by reference in its entirety. For example, the one or more batteries 104 of the electric vehicle 102 may be charged at one or more charge stations 132, which may be located on private property (e.g., the home of the user 110, etc.), on public property (e.g., parking lots, curbside parking, etc.), or at/near battery exchange stations 134. Furthermore, in some embodiments, the one or more batteries 104 of the electric vehicle 102 may be exchanged for charged batteries at the one or more battery exchange stations 134 within the electric vehicle network 100.

Thus, if a user is traveling a distance beyond the range of a single charge of the one or more batteries 104 of the electric vehicle 102, the spent (or partially spent) batteries may be exchanged for charged batteries so that the user can continue with his/her travels without waiting for the battery pack to be recharged. The term “battery service station” is used herein to refer to battery exchange stations (e.g., battery exchange station 134), which exchange spent (or partially spent) batteries of the electric vehicle for charged batteries, and/or charge stations (e.g., charge station 132), which provide energy to charge a battery pack of an electric vehicle. Furthermore, the term “charge spot” may also be used herein to refer to a “charge station.”

As illustrated in FIG. 1, a communications network 120 may be used to couple the vehicle 102 to a control center system 112, a charge station 132, and/or a battery service station 134. Note that for the sake of clarity, only one vehicle 102, one battery 104, one charge station 132, and one battery exchange station 134 is illustrated, but the electric vehicle network 100 may include any number of vehicles, batteries, charge stations, and/or battery exchange stations, etc. Furthermore, the electric vehicle network 100 may include zero or more charge stations 132 and/or battery exchange stations 134. For example, the electric vehicle network 100 may only include charge stations 132. On the other hand, the electric vehicle network 100 may only include battery exchange stations 134. In some embodiments, any of the vehicle 102, the control center system 112, the charge station 132, and/or the battery exchange station 134 includes a communication module that can be used to communicate with each other through the communications network 120.

The communications network 120 may include any type of wired or wireless communication network capable of coupling together computing nodes. This includes, but is not limited to, a local area network, a wide area network, or a combination of networks. In some embodiments, the communications network 120 is a wireless data network including: a cellular network, a Wi-Fi network, a WiMAX network, an EDGE network, a GPRS network, an EV-DO network, a “3GPP LTE” network, a “4G” network, an RTT network, a HSPA network, a UTMS network, a Flash-OFDM network, an iBurst network, and any combination of the aforementioned networks. In some embodiments, the communications network 120 includes the Internet.

In some embodiments, the electric vehicle 102 includes a positioning system 105. The positioning system 105 may include: a satellite positioning system, a radio tower positioning system, a Wi-Fi positioning system, and any combination of the aforementioned positioning systems. The positioning system 105 is used to determine the geographic location of the electric vehicle 102 based on information received from a positioning network. The positioning network may include: a network of satellites in a global satellite navigation system (e.g., GPS, GLONASS, Galileo, etc.), a network of beacons in a local positioning system (e.g., using ultrasonic positioning, laser positioning, etc.), a network of radio towers, a network of Wi-Fi base stations, and any combination of the aforementioned positioning networks. Furthermore, the positioning system 105 may include a navigation system that generates routes and/or guidance (e.g., turn-by-turn or point-by-point, etc.) between a current geographic location of the electric vehicle and a destination.

In some embodiments, the navigation system receives a destination selection from a user 110, and provides driving directions to that destination. In some embodiments, the navigation system communicates with the control center system 112, and receives battery service center recommendations (as well as other data) from the control center system 112.

In some embodiments, the electric vehicle 102 includes a communication module 106, including hardware and software, that is used to communicate with the control center system 112 (e.g., associated with a service provider of the electric vehicle network 100) and/or other communication devices via a communications network (e.g., the communications network 120).

In some embodiments, the control center system 112 periodically provides a list of suitable service stations 130 (e.g., within the maximum theoretical range of the electric vehicle; has the correct type of batteries; etc.) and respective status information to the electric vehicle 102 via the communications network 120. The status of a battery service station 130 may include: a number of charge stations of the respective battery service station that are occupied, a number of suitable charge stations of the respective battery service station that are free, an estimated time until charge completion for respective vehicles charging at respective charge stations, a number of suitable battery exchange bays of the respective battery service station that are occupied, a number of suitable battery exchange bays of the respective battery service station that are free, a number of suitable charged batteries available at the respective battery service station, a number of spent batteries at the respective battery service station, the types of batteries available at the respective battery service station, an estimated time until a respective spent battery is recharged, an estimated time until a respective exchange bay will become free, a location of the battery service station, battery exchange times, and any combination of the aforementioned statuses.

In some embodiments, the control center system 112 also provides access to the battery service stations to the electric vehicle 102. For example, the control center system 112 may instruct a charge station to provide energy to recharge the one or more batteries 104 after determining that an account for the user 110 is in good standing. Similarly, the control center system 112 may instruct a battery exchange station to commence the battery exchange process after determining that the account for the user 110 is in good standing.

The control center system 112 obtains information about the electric vehicles 102 and/or battery service stations 130 by sending queries through the communications network 120 to the electric vehicle 102 and to the battery service stations 130 (e.g., charge stations, battery exchange stations, etc.) within the electric vehicle network 100. For example, the control center system 112 can query the electric vehicle 102 to determine a geographic location of the electric vehicle and a status of the one or more batteries 104 of the electric vehicle 102. The control center system 112 can also query the electric vehicle 102 to identify a user-selected final destination of the vehicle 102. The control center system 112 may also query the battery service stations 130 to determine the status of the battery service stations 130. The status of battery service stations includes, for example, information about the replacement batteries 114 at an exchange station 134 (including the number and charge status of those batteries), reservation information for replacement batteries 114 or charge spots, etc.

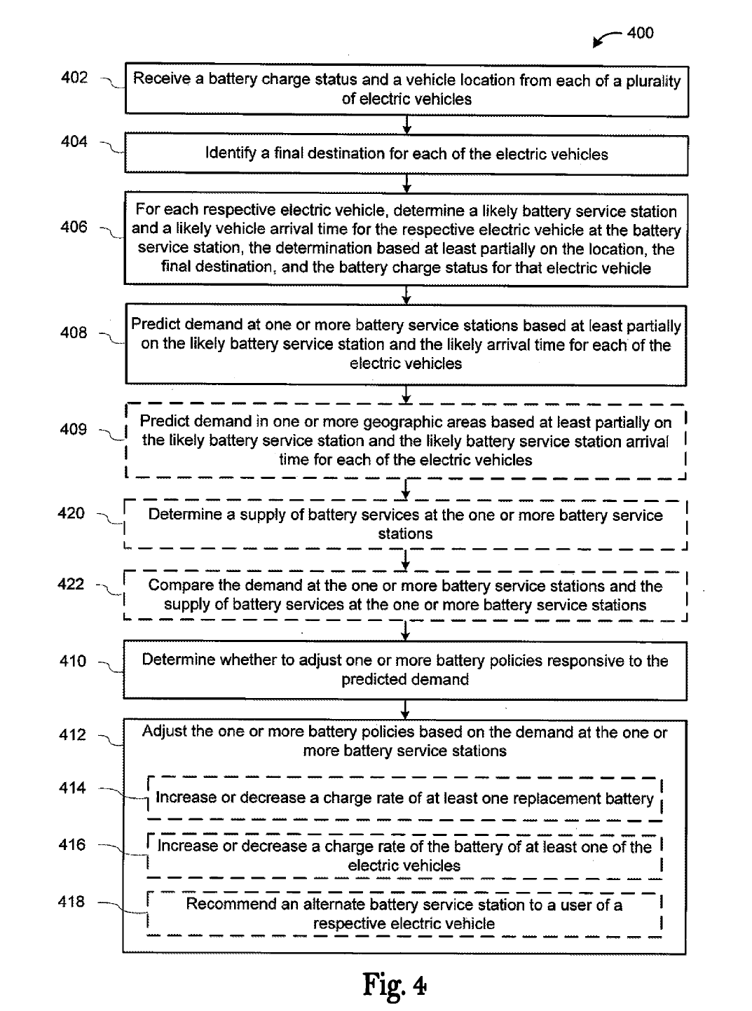

The control center system 112 also sends information and/or commands through the communications network 120 to the electric vehicle 102. For example, the control center system 112 may send a battery service station recommendation to a user 110 of an electric vehicle 102. The control center system 112 may alternatively send a recommendation of type of battery service station to a user 110. Such recommendations are described in greater detail herein with respect to FIG. 4.

The control center system 112 may also send information and/or commands through the communications network 120 to the battery service stations 130. For example, the control center system 112 may send an instruction to increase or decrease a charge rate of one or more replacement batteries 114 coupled to the electric vehicle network 100 at the battery service station. The control center system 112 may send an instruction to a battery service station 130 to change (i.e., increase or decrease) the number of available replacement batteries 114 at a battery service station (e.g., by acquiring batteries from a different battery service station, or a battery storage location). Such instructions are described in greater detail herein with respect to FIG. 4.

In some embodiments, the battery service stations 130 provide status information to the control center system 112 via the communications network 120 directly (e.g., via a wired or wireless connection using the communications network 120). In some embodiments, the information transmitted between the battery service stations 130 and the control center system 112 is transmitted in real-time. In some embodiments, the information transmitted between the battery service stations 130 and the control center system 112 are transmitted periodically (e.g., once per minute).

As illustrated in FIG. 1, the electric vehicle network 100 may include a power network 140. The power network 140 can include power generators 156, power transmission lines, power substations, transformers, etc., which facilitate the generation and transmission of electrical power. The power generators 156 may include any type of energy generation plants, such as wind-powered plants 150, fossil-fuel powered plants 152, solar powered plants 154, biofuel powered plants, nuclear powered plants, wave powered plants, geothermal powered plants, natural gas powered plants, hydroelectric powered plants, and a combination of the aforementioned power plants, or the like. The energy generated by the one or more power generators 156 may be distributed through the power network 140 to charge stations 132 and/or battery exchange stations 134. The power network 140 can also include batteries such as the battery 104 of the vehicle 102, replacement batteries 114 at battery exchange stations, and/or batteries that are not associated with vehicles, such as storage batteries. Thus, energy generated by the power generators 156 can be stored in these batteries and extracted when energy demand exceeds energy generation.

All of the components connected to the power network 140 (including power generators 156, and any load source, such as batteries 104, 114, etc) may be coupled to (and may be a part of) a power grid for transmitting electrical energy between the various components. The power grid may include transmission components of various capacities, from long distance, high-voltage transmission, to low-voltage, residential and/or commercial wiring.

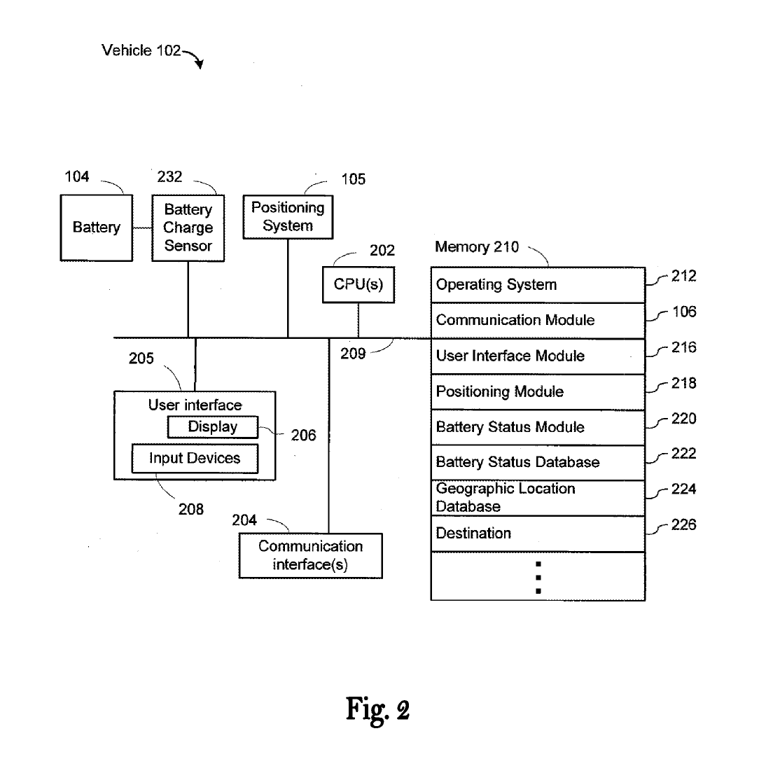

FIG. 2 is a block diagram illustrating components of a vehicle 102 in accordance with some embodiments. The vehicle 102 in this example includes one or more processing units (CPU's) 202, one or more network or other communications interfaces 204 (e.g., antennas, I/O interfaces, etc.), memory 210, a positioning system 105, a battery charge sensor 232 that is connected to or communicates with the battery 104, and determines the status of the battery 104, and one or more communication buses 209 for interconnecting these components. The communication buses 209 may include circuitry (sometimes called a chipset) that interconnects and controls communications between system components. The vehicle 102 optionally may include a user interface 205 comprising a display device 206 and input devices 208 (e.g., a mouse, a keyboard/keypad, a touchpad, a touch screen, etc.). Memory 210 may include high-speed random access memory, such as DRAM, SRAM, DDR RAM or other random access solid state memory devices and/or non-volatile memory, such as one or more magnetic disk storage devices, optical disk storage devices, flash memory devices, or other non-volatile solid state storage devices. The memory 210 may optionally include one or more storage devices remotely located from the CPU(s) 202. The memory 210, or alternately the non-volatile memory device(s) within memory 210, comprises a computer readable storage medium. In some embodiments, the memory 210 stores the following programs, software modules and data structures, or a subset thereof:
an operating system 212 that includes procedures for handling various basic system services and for performing hardware dependent tasks;
a communication module 106 that is used for connecting the vehicle 102 to other computers (e.g., a computer associated with an electric vehicle network provider) via the one or more communication network interfaces 204 (wired or wireless) and one or more communication networks, such as the Internet, other wide area networks, local area networks, metropolitan area networks, and so on;
a user interface module 216 that receives commands from the user via the input devices 208 and generates user interface objects in the display device 206;
in some embodiments, a positioning module 218 that determines and stores the position of the vehicle 102 using a positioning system as described herein; and in other embodiments stores a destination 226 that is selected by the user of the vehicle;
a battery status module 220 that determines the status of a battery of a vehicle (e.g., employing voltmeters, ammeters, PH-meters, and/or thermometers);
battery status database 222 that includes present and/or historical information about the status of the battery of the vehicle; and/or
a geographic location database 224 of the vehicle that stores the present location and/or historical locations or addresses of the vehicle's location.

It should be noted that the positioning system 105 (and the positioning module 218), the vehicle communication module 106, the user interface module 216, the battery status module 220, the battery status database 222, and/or the geographic location database 224 can be referred to as the “vehicle operating system.”

It should also be noted that although a single vehicle 102 is discussed herein, the methods and systems can be applied to a plurality of vehicles 102.

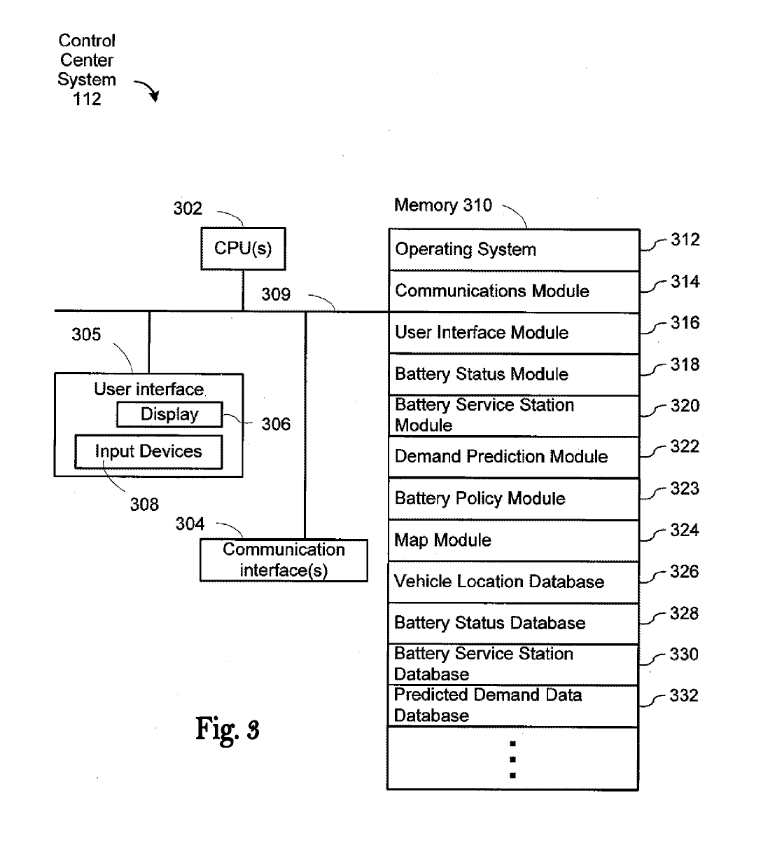

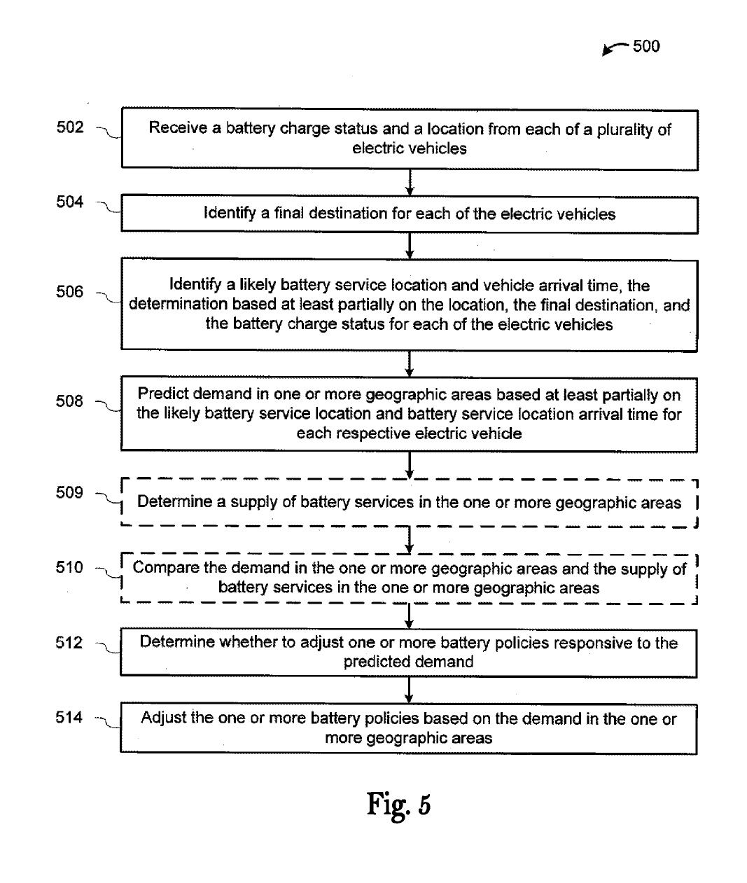

FIG. 3 is a block diagram illustrating a control center system 112 in accordance with some embodiments. The control center system 112 can be a computer system of a service provider. In this example the control center system 112 includes one or more processing units (CPU's) 302, one or more network or other communications interfaces 304 (e.g., antennas, I/O interfaces, etc.), memory 310, and one or more communication buses 309 for interconnecting these components. The communication buses 309 are similar to the communication buses 209 described above. The control center system 112 optionally may include a user interface 305 comprising a display device 306 and input devices 308 (e.g., a mouse, a keyboard, a touchpad, a touch screen, etc.). Memory 310 includes high-speed random access memory, such as DRAM, SRAM, DDR RAM or other random access solid state memory devices; and may include non-volatile memory, such as one or more magnetic disk storage devices, optical disk storage devices, flash memory devices, or other non-volatile solid state storage devices. Memory 310 may optionally include one or more storage devices remotely located from the CPU(s) 302. Memory 310, or alternatively the non-volatile memory device(s) within memory 310, comprises a computer readable storage medium. In some embodiments, memory 310 stores the following programs, modules and data structures, or a subset thereof:
an operating system 312 that includes procedures for handling various basic system services and for performing hardware dependent tasks;
a communication module 314 that is used for connecting the control center system 112 to other computing devices via the one or more communication network interfaces 304 (wired or wireless) and one or more communication networks, such as the Internet, other wide area networks, local area networks, metropolitan area networks, and so on;
a user interface module 316 that receives commands from a user via the input devices 308 and generates user interface objects in the display device 306;
a battery status module 318 that receives (e.g., via communication module 314) and/or determines (e.g., based on location, route and/or historical data associated with each specific vehicle) the status of the batteries of a fleet of vehicles;
a battery service station module 320 that tracks the status of battery service stations e.g., based on status data received via the communication module 314;
a demand prediction module 322 that predicts demand at battery service stations and/or demand in certain geographic areas e.g., based on one or more of the methods described with reference to FIG. 4 and FIG. 5;
a battery policy module 323 that determines whether to adjust one or more battery policies of the electric vehicle network;
a map module 324 that generates maps/displays representing predicted demand values at battery service stations and/or in certain geographic areas;
a vehicle location database 326 that includes the present location and/or historical locations of vehicles in the vehicle-area network;
a battery status database 328 that includes the statuses of batteries (e.g., 104 of vehicles and/or replacement batteries 114) in the vehicle-area network;
a battery service station database 330 that includes the statuses of battery service stations in the vehicle-area network; and
a predicted demand database 332 that includes the demand prediction data at battery service stations and/or in certain geographic areas.

Each of the elements identified above in FIGS. 2 and 3 may be stored in one or more of the previously mentioned memory devices, and corresponds to a set of instructions for performing a function described above. The set of instructions can be executed by one or more processors (e.g., the CPUs 202, 302). The above identified modules or programs (i.e., sets of instructions) need not be implemented as separate software programs, procedures or modules, and thus various subsets of these modules may be combined or otherwise re-arranged in various embodiments. In some embodiments, memories 210, 310 may store a subset of the modules and data structures identified above. Furthermore, memories 210, 310 may store additional modules and data structures not described above.

The following are some examples of the demand prediction methods.

FIG. 4 is a flow diagram of a method 400 for managing an electric vehicle network 100, according to some embodiments. In particular, the method 400 allows an electric vehicle network service provider to adjust one or more battery policies based on predicted demand of the electric vehicle network infrastructure, including demand for services provided at battery service stations. In some embodiments, the method 400 is performed at the control center system 112, using one or more of the components, modules, and databases described above with reference to FIG. 3.

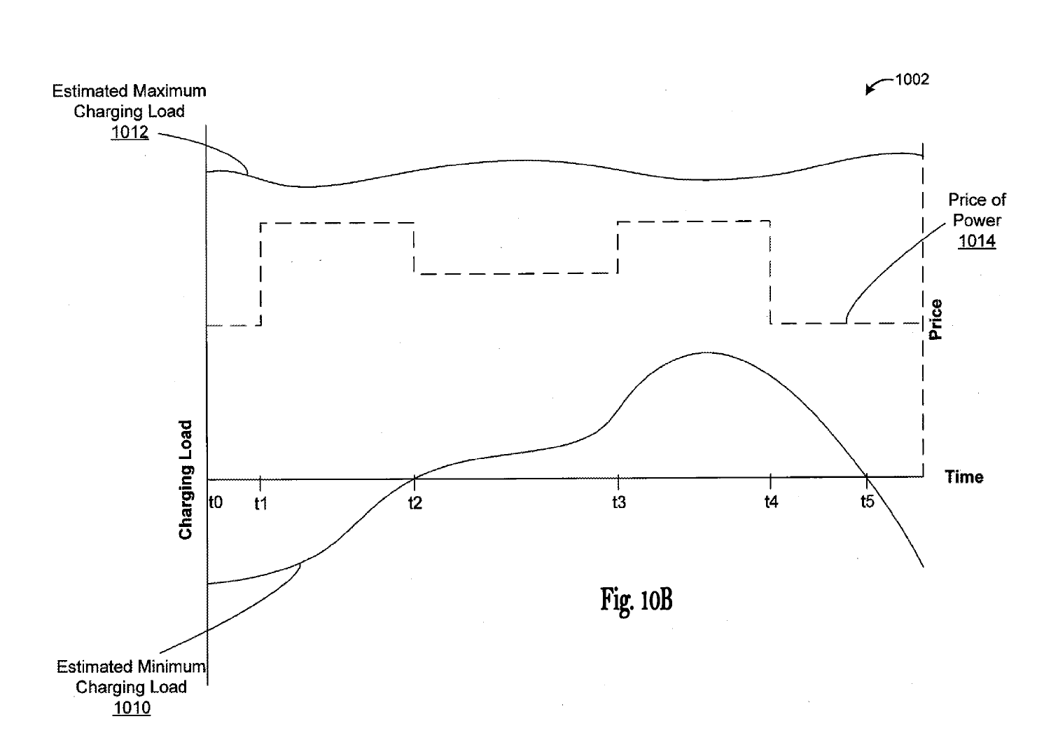

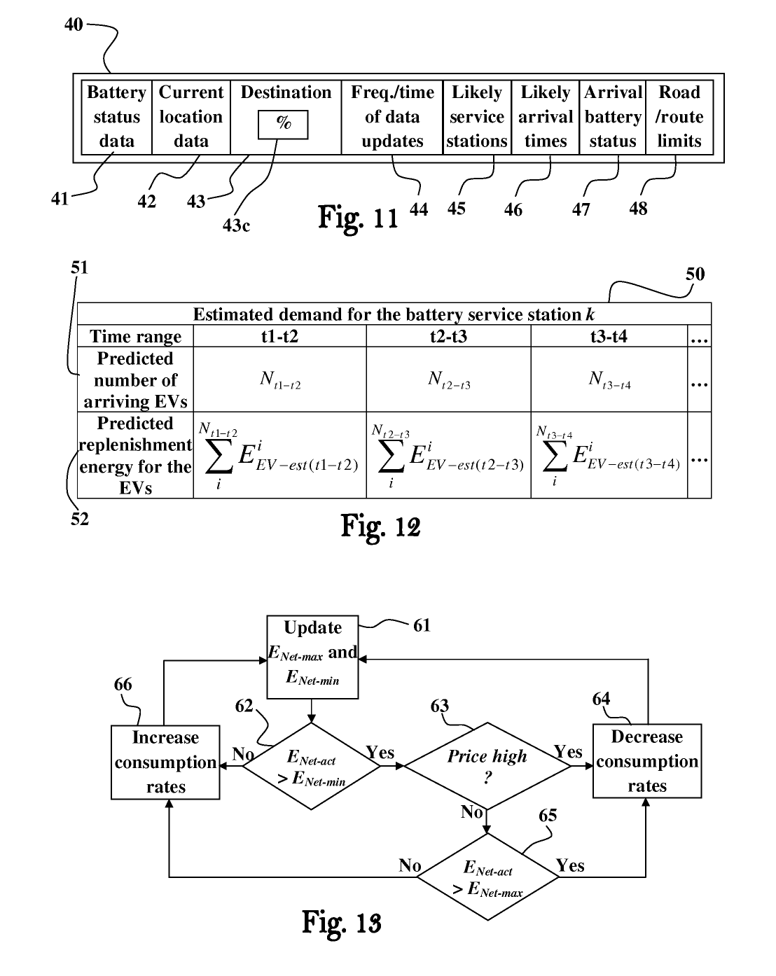

The process illustrated in FIG. 4 is described hereinbelow in conjunction with the vehicle data record 40 illustrated in FIG. 11. The vehicle data record 40 may be stored and updated in the memory 310 of the control center system 112 and/or in the memory 210 of vehicle 102.

The control center system 112 receives (402) battery status data 41 and location data 42 from each of a plurality of electric vehicles 102. In some embodiments, the battery status data 41 and the location data 42 of a respective vehicle 102 are transmitted from the vehicle's communications module 106, via the communications network 120, to the control center system 112. The location data 42 of the respective vehicle 102 corresponds to a current or recent location (e.g., where the vehicle is unable to determine its present location, or where there is a delay in transmission of position data), and is typically represented as a location in a geographic coordinate system (e.g., with a latitude and longitude coordinate pair). In some embodiments, the battery status data 41 includes battery charge status data e.g., the amount of electrical energy remaining in a battery 104 of the respective vehicle 102. In some embodiments, the battery status data 41 includes data indicative of a remaining driving range e.g., travelable distance, of the vehicle 102 based on the remaining electrical energy (i.e., charge level) of the battery 104.

The control center system 112 identifies (404) a final destination 43 for each of the electric vehicles 102. In some embodiments, a user 110 enters a final or intended destination into a navigation system (e.g., the positioning system 105) of the vehicle 102. In such cases, the user-identified final destination 43 is transmitted from the vehicle's communication module 106, via the communications network 120, and received by the control center system 112. The control center system 112 then identifies (404) the selected destination as the final destination 43 for that vehicle. If a user 110 changes a final or intended destination in the navigation system of the vehicle 102, the new user-identified final destination is transmitted to the control center system 112. Thus, the control center 110 can update the final destination 43 data for that vehicle.

In some cases, a user 110 enters an intended destination into the navigation system, but then decides to travel to a different destination without re-entering or otherwise changing the previously entered destination. In these circumstances, the control center 110 can monitor the vehicle's location and movements, and detect when a user has abandoned a user-selected destination 43. For instance, in some embodiments, if the vehicle's location is within a predetermined distance from a recommended or likely driving route to the user-selected destination, the control center system 112 or the vehicle's navigation system determines that the user 110 has abandoned that destination. The control center system 112 or the vehicle's navigation system then attempts to predict the likely final destination 43 of the vehicle, as described in greater detail below.

In some embodiments, the control center system 112 uses one or more prediction methods to identify the final destination 43 for a respective electric vehicle. See, e.g., U.S. patent application Ser. No. 12/560,337, which is hereby incorporated by reference in its entirety. In some embodiments, the control center system 112 identifies a final destination 43 for a respective electric vehicle 102 based on historical travel data for a respective user 110 e.g., by querying the vehicle location database 326 to determine historical vehicle location data recorded during certain times of the day, week and/or month. In one example, the control center system 112 determines that a respective user 110 typically travels to a home location, along a particular route, at a particular time each weekday. The control center system 112 then uses this historical data to determine that, when the user 110 is on that particular route at that particular time, the user 110 is likely traveling home. Thus, the control center system 112 can predict that the home location is the user's final destination 43. In some embodiments, the control center system 112 predicts that the final destination 43 of a vehicle will be a home location, a work location, a battery service station, a previously visited location, or a frequently visited location.

The control center system 112 can also predict a respective user's final destination 43 irrespective of that user's particular driving history. For example, in some embodiments, the control center system 112 uses a list of frequently visited locations for a population to predict a likely destination 43 of a particular user 110. For example, if most vehicles on a certain section of highway ultimately travel to San Jose, Calif., it is more likely that any single vehicle on that same highway is also on its way to San Jose, Calif. Thus, the control center system 112 can use aggregated destination data from a fleet of vehicles to identify a final destination 43 for a particular vehicle based on that vehicle's location data 42.

A final destination 43 for a vehicle may be identified (404) at any geographic resolution. For example, while the control center system 112 may not be able to predict the exact building or street to which a particular vehicle is traveling, it may be able to determine that the vehicle is most likely traveling to a particular city or town, or a particular area of a city. In some embodiments, when a final destination is predicted for a particular user 110, the destination is associated (e.g., at the control center system 112) with a confidence value 43c indicating the relative confidence of the prediction (e.g., that the prediction has a 70% confidence value), or an uncertainty value of the prediction (e.g., plus or minus 10 miles). One of skill in the art will recognize that other values, factors, or scales can be used to indicate the relative confidence 43c, error, or resolution of the location prediction 43. In the instant application, “determining” a final destination simply means that the final destination 43 is established to an acceptable degree of certainty (43c), and does not necessarily indicate that a vehicle is guaranteed to travel to that destination.

The control center system 112 can also identify (404) a final destination 43 of a vehicle 102 even when the vehicle 102 is not currently moving. In some embodiments, the control center system 112 identifies a likely final destination 43 for a stationary vehicle 102 based on historical data for that particular vehicle e.g., using data stored in the vehicle location database 326. For example, the control center system 112 may detect that a certain vehicle 102 is typically parked from 9:00 AM to 5:00 PM at a first location (e.g., a work location), and then at 5:00 PM, the vehicle 102 travels to a second location (e.g., a home location). Thus, in some embodiments, the control center system 112 predicts a final destination 43 for a stationary vehicle 102 based on historical data of the vehicle, or of the user 110 of the vehicle 102.

In some embodiments, the control center system 112 periodically (or intermittently) receives the battery status data 41 and the location data 42 of the plurality of electric vehicles 102 in the electric vehicle network 100 in order to update the identified final destinations 43 for each of the electric vehicles. In some embodiments, the control center system 112 periodically identifies the likely final destination for each electric vehicle 102. By periodically identifying the likely final destination of the vehicle 102, the control center system 112 effectively updates the destination data 43 for the electric vehicles 102, and thus has the most current destination data when predicting demand at the battery service stations 130, as discussed below. In some embodiments, the control center system 112 receives the battery status data 41 and the location data 42 of the electric vehicles at a predetermined time interval. In some embodiments, the battery status data 41 and the location data 42 of the vehicles are received by the control center system 112 every minute, thirty seconds, or at other time intervals, or based on other triggering events. For example, the charge and location information may be received more frequently when a vehicle 102 is in a more congested area, and less frequently when it is in a less congested area.

In some embodiments, the control center system 112 determines the frequency and time 44 at which the battery status data 41 and the location data 42 updates of the vehicles are transmitted to the control center system 112. In some embodiments, each respective vehicle 102 determines the frequency and time 44 at which such information updates are transmitted to the control center system 112. In some embodiments, the control center system 112 and each respective vehicle 102 share the task of determining when and/or how frequently (44) to update the battery status (41) and location (42) data information.

The control center system 112, or a vehicle's navigation system, determines (406) a likely battery service station 45 and a likely vehicle arrival time 46 for each of the electric vehicles 102. In some embodiments, users 110 will actually select a respective battery service station 130 as an intended destination (45) in a vehicle's navigation system.

In other embodiments, the control center system 112, or a vehicle's computer system e.g., navigation system, determines (406) a likely battery service station 45 and a likely vehicle arrival time 46 based at least partially on the location data 42, the final destination 43, and the battery status data 41 for each of the electric vehicles 102. For example, because the control center system 112 has the current location data 42, the final destination 43 (either selected by a user or predicted by the control center system 112), and the battery status data 41 of a respective electric vehicle 102, the control center system 112 can determine a particular battery service station 45 that the vehicle is likely to visit.

The data of each vehicle data record 40 may be gathered and updated for each vehicle 102 in the memory 310 of the control center system 112 based on data received from the vehicles 102 and/or based on data extracted/determined from/by the various databases/modules (depicted in FIG. 3) of the control center system 112. The gathered data may be then used by the processor 302 and/or the demand prediction module 322 to determine the likely service stations 45 and arrival times 46, and the arrival battery status 47, for each respective vehicle 102, and based thereon to predict the demand 50 at one or more battery service stations and/or geographical regions.

In some embodiments, the control center system 112 first identifies a set of candidate battery service stations that are reachable by a vehicle. For example, the control center system 112 may determine (or extract) from battery status data 41 the travelable distance of a specific vehicle and then based on the current location data 42 of the vehicle 102 extract from the battery service station database 330 a set of reachable battery service stations located within the range defined by the current location data 42 and the travelable distance of the vehicle 102. The control center system 112 then determines which one of the candidate service stations the vehicle is likely to visit.

For example, if a vehicle is 100 miles outside of San Francisco, Calif., and is traveling to San Francisco along a particular highway, and its battery status data 41 indicates that the remaining battery energy (charge level) may provide a travelable distance of about 50 miles, the control center system 112 may predict that the vehicle 102 is likely to stop at a battery service station somewhere along that particular highway within 50 miles of the vehicle's current location 42. The control center system 112 can then identify a set of candidate battery service stations that are within 50 miles of the vehicle, and between the vehicle's current location and San Francisco. In some embodiments, the control center system 112 identifies battery service stations that are located within a short distance from the particular highway or road on which the vehicle is traveling, such as near an exit of the highway. In some embodiments, the control center system 112 also determines the battery status (e.g., charge level) at which a particular user is likely to visit a battery service station 130. For example, the control center system 112 may have stored historical data for a particular user 110 that the user typically exchanges or charges the battery of his vehicle when the vehicle's battery still has enough charge to travel 15 miles. For instance, returning to the previously discussed example, the control center system 112 may determine that the particular user 110 is most likely to pick a service station along his route to San Francisco, approximately 35 miles from his current location (42). This can help the control center system 112 narrow the number of candidate battery service stations at which the user 110 is likely to stop.

In some embodiments, the control center system 112 uses aggregated charging behavior of many individual users to help predict the battery status 47 at which a particular user is likely to visit a battery service station 130. For example, the control center system 112 may aggregate charging data for a group of users and determine that, on average, most drivers recharge or exchange their vehicle's battery when the battery has enough charge to travel 25 miles. Thus, the control center system 112 may determine that an average user is likely to charge or exchange a battery when it has 25 miles of remaining driving range.

The control center system 112 also determines (406) a likely vehicle arrival time 46 for each of the electric vehicles. In some embodiments, the vehicle communication module 106 of a vehicle 102 transmits navigation information (e.g., from the positioning system 105) to the control center system 112. In some embodiments, the navigation information includes speed, location, and/or direction data. In some embodiments, the communication module 106 periodically sends location data 42 to the control center system 112, and the control center calculates speed and direction data based on the time change of the vehicle's location. The control center system 112 then uses this information (e.g., the speed of the vehicle and the remaining distance to the likely battery service station 130) and determines a time 46 at (or near) which the user is likely to arrive at the likely battery service station. In some embodiments, the navigation system of a vehicle makes this determination, and provides the vehicle arrival time 46 to the control center system 112.

In some embodiments, the control center system 112 uses additional information to provide more accurate predictions, such as traffic and/or speed limit data 48 for the route to the likely battery service station. In some embodiments, the speed is a calculated likely speed of the respective electric vehicle based on a collective average speed of a group of other vehicles in proximity to the respective electric vehicle. In other words, a respective vehicle 102 may be associated with or assigned an average speed of a group of cars on the same or nearby portion of road as the respective vehicle 102. In some embodiments, a respective vehicle 102 may be associated with or assigned a speed based on historical speed data for a particular road for that day and time.

The control center system 112 may be configured to predict (408) demand at one or more battery service stations. FIG. 12 schematically illustrates a demand table 50 predicted for a specific battery service station 130 according to some possible embodiments. In some embodiments, the prediction is based at least partially on the likely battery service station 45 for each of the electric vehicles, and may optionally further utilize the likely vehicle arrival time 46 for each of the electric vehicles to predict loads over specific times and/or time ranges. For example, and as described above, the control center system 112 determines a likely battery service station 45 and arrival time 46 for each of a plurality of vehicles. Based on this data, the control center system 112 determines a certain number of the plurality of vehicles that are likely to visit a particular battery service station at (or near) a given time. For example, in some embodiments, the control center system 112 determines that a certain number of vehicles (e.g., Nₜ₁₋ₜ₂) are likely to visit a battery service station k within a certain time window (e.g., t1-t2), as exemplified in row 51 of the demand table 50.

In some embodiments, the demand for a respective battery service station 130 is represented by a number of cars requiring service (either battery charging or battery exchange) at the respective battery service station 130. In some embodiments, the demand is represented by an amount of energy (E^{(k)}_{SS-est}, amount of replenishment energy predicted for service station k, where k is a positive integer) required by a set of vehicles (Eⁱ_{EV-est}, amount of replenishment energy predicted for vehicle i, where i is a positive integer) that are likely to visit a respective battery service station (k) 130, e.g.,

$${E}_{SS - est}^{( k )} = {Σ}_{i}^{N} {E}_{EV - est}^{i} ,$$

as exemplified in row 52 of the demand table 50.

In some embodiments, the control center system 112 predicts (409) demand (e.g.,

$${Σ}_{k ∈ region} {E}_{SS - est}^{( k )} )$$

in one or more geographic areas or regions based at least partially on the demand at each of a subset of the one or more battery service stations. In other words, the control center system 112 uses the demand data (50) of multiple individual battery service stations (k) in order to determine the average demand

$$( {Σ}_{k ∈ region} {E}_{SS - est}^{( k )} \text{/} {N}_{region} )$$

for a larger geographic area that encompasses (or is associated with) those individual battery service stations (k).

For instance, a geographic area that encompasses many battery service stations 130 may have a substantially lower average demand than any one service station within that area. Accordingly, it is sometimes advantageous for the control center system 112 to assume that most users who need battery services in a particular geographic area will be able to find nearby battery services when they are required, even if a single service station in that area is unable to provide the services at that time. Thus, in some embodiments, the control center system 112 aggregates the predicted demand data 50 for all of (or at least some of) the battery service stations 130 within a particular geographic area to determine the predicted demand for that geographic area. In some embodiments, the control center system 112 averages the predicted demand data for all of (or at least some of) the battery service stations within a particular geographic area to determine the predicted demand for that geographic area.

In some embodiments, the demand prediction may be a demand at a specific time, or a demand over a time range. For example, the control center system 112 may determine that a battery service station will have a certain demand at a specific time (e.g., at 5:30 PM), or over a future time interval (e.g., between 6:45 PM and 7:00 PM).

Demand predictions can be made for many future time intervals, extending several minutes, hours, or days into the future. Predictions for the immediate future are likely to be more accurate than more distant predictions, as the control center system 112 is more likely to accurately identify the final destinations 43 of the vehicles 102 and determine the likely battery service stations 45 and arrival times 46 for the vehicles 102. In some embodiments, the control center system 112 also makes longer term predictions of demand based on historical destination data for a population of vehicles.

In some embodiments, the control center system 112 records historical demand data for at least a subset of the service stations 130 in the electric vehicle network 100. The historical demand data is then analyzed to determine demand trends over time. For example, the historical data may indicate that, on average, fifty vehicles demand battery exchanges at a particular battery exchange station 134 between 5:00 PM and 5:30 PM on Monday evenings. The control center system 112 uses the historical data to make predictions even when final destinations 43 are not available for individual respective vehicles 102, or in addition to predictions based on final destination of individual vehicles 102.

As described above, the control center system 112 predicts a demand 50 at one or more battery service stations based on data received from a plurality of vehicles 102. However, it may not always be possible to predict final destinations 43 for every single vehicle that may visit a battery service station 130. It may therefore be beneficial to include a factor of safety in the demand prediction algorithms in order to accommodate these vehicles. Thus, in some embodiments, the demand value for one or more battery service stations is increased to account for the added demand resulting from one or more electric vehicles of a second plurality of electric vehicles. In some embodiments, the second plurality of electric vehicles are vehicles for which final destinations 43 cannot be predicted, vehicles that are unable to communicate with the control center system 112 (for example, because they do not have the necessary communication systems, or their communication systems are otherwise inoperative), or vehicles that visit a battery exchange station 130 other than the one predicted (45) by the control center system 112 or selected by the user 110.

In some embodiments, the demand value(s) that is ultimately associated with a battery service station is 150% of the calculated demand (50). For example, if a calculated demand indicates that 20 vehicles are likely to require a battery exchange at a particular battery exchange station 134 within a time range, the ultimate associated demand value for that battery exchange station 134 (including the factor of safety) is 30 vehicles. In some embodiments, in order to account for the additional demand from vehicles 102 that are not in active communication with the control center system 112, historical demand data is used to supplement the demand predictions. For example, in some embodiments, the control center system 112 determines that an actual historical demand (E^{(k)}_{SS-act-Hist(ta-tb)}) at a battery service station was a certain amount (ΔE) above the predicted demand (E^{(k)}_{SS-est-Hist(ta-tb)}) on a particular historical date and time (E^{(k)}_{SS-act-Hist(ta-tb)}=E^{(k)}_{SS-est-Hist(ta-tb)}+ΔE). The control center system 112 thus increases the present demand value for that battery service station by that amount (e.g., E^{(k)}_{SS-est(ta-tb)}+ΔE). In some embodiments, the control center system 112 uses actual historical demand values (E^{(k)}_{SS-act-Hist(ta-tb)}) from a certain past time period, such as the same day from the previous week (e.g., so that demand values from a corresponding day of the week are used), and/or the same day from the previous year (e.g., so that seasonal or weekly changes in demand are accounted for). Accordingly, the predicted demand values can be augmented or modified based on data from a historical time similar to the present time, which will typically more closely track the actual demand at the present time.

In some embodiments, the control center system 112 informs a utility provider of an expected power demand, where the expected power demand is based at least partially on the predicted demand at the one or more battery service stations. Often, service providers of electric vehicle networks will have close relationships with the utility providers (e.g., providers and/or operators of the power generators 156 or a power grid). It can therefore be beneficial for the control center 112 to inform the utility providers of the expected power demand (50) of the battery service stations 130 (or the geographic areas). The utility providers can then be prepared for potentially substantial increases or decreases in the power demand of the electric vehicle network. This may be particularly important during times of peak driving hours, as many thousands of electric vehicles may demand charging services at substantially the same time. In some embodiments, utility providers and electric vehicle network providers may negotiate power pricing based on the service provider's ability to predict demand and provide demand data to the utility providers, or on the service provider's ability to control demand to suit the utility providers.

The control center system 112 determines (410) whether to adjust one or more battery policies responsive to the predicted demand. In some embodiments, battery policies are adjusted to help satisfy battery charging and battery exchange demands for electric vehicles 102 of the electric vehicle network 100. In some embodiments, battery policies are adjusted in order to alleviate a high demand at a respective battery service station 130. Battery policies include, but are not limited to: charging rates of replacement batteries 114 at battery exchange stations 134; charging rates of batteries 104 in vehicles 102 that are currently plugged in to the electric vehicle network 100; a number of replacement batteries 114 provided at a particular battery exchange station 134; reservations of services at battery service stations 130 (e.g., battery exchange lanes or charging spots); and recommendations of battery service stations 130 made by the control center system 112.

In some embodiments, the control center system 112 determines (420) a supply of battery services at the one or more battery service stations. The supply of battery services may be any measure of the capacity of a battery exchange station 134 or a charge station 132. For example, the “supply” of a battery exchange station 134 may be a rate at which vehicle batteries can be exchanged (e.g., 50 batteries per hour), a number of available fully charged replacement batteries 114, a number or exchange bays, and/or a number of available battery exchange reservations. The “supply” of a charge station 132 may be a rate at which vehicle batteries can be charged from a given charge spot (e.g., 30 minutes to full charge), the number of available charge spots, and/or the number of available charge spot reservations.

In some embodiments, the supply of battery services at the battery service stations 130 in the electric vehicle network 100 is received by the control center system 112. In some embodiments, the battery service station module queries one or more of the battery service stations 130 in the electric vehicle network to request supply information. Supply information for battery exchange stations 134 and battery charge stations 132 are described above. In some embodiments, supply information is stored in the battery service station database 330. In some embodiments, the demand prediction module 322 of the control center system 112 accesses the supply information in the battery service station database 330 when comparing (422) the supply and demand values within the electric vehicle network 100, as described in greater detail below.

In some embodiments, the control center system 112 compares (422) the demand at the one or more battery services stations and the supply of battery services at the one or more battery service stations. Accordingly, the control center system 112 can determine whether the demand at a particular battery service station 130 outstrips the supply of battery services available there. In other words, in some embodiments, the control center system 112 determines the level of congestion that is experienced at a respective battery service station 130 based on the supply and the demand of battery services at that service station. Furthermore, the determination and comparison of the supply and the demand of battery services may be granularized for a particular type of battery service. For example, a battery service station 130 that includes both battery charging and battery exchange facilities may have insufficient charge spots to meet a predicted demand for charging, but have adequate supplies of replacement batteries 114 to satisfy the predicted demand for exchange services. Thus, the control center system 112 can separately compare the supply and demand for each of the types of battery services at a respective battery service station 130.

In some embodiments, the comparison between the supply and demand of battery services results in a determination that the supply of battery services within a larger geographic area (rather than at a specific battery service station) is exceeded by the likely demand for battery services in that area.

In some embodiments, the control center system 112 adjusts (412) the one or more battery policies based on the demand at the one or more battery service stations. In some embodiments, adjusting the battery policies includes increasing or decreasing (414) a charge rate of at least one replacement battery 114 coupled to the power grid associated with the electric vehicle network 100 at a battery service station 130. For example, if the control center system 112 predicts that there will be a high demand for replacement batteries 114 at a particular battery exchange station 134, the control center system 112 may instruct the exchange station 134 to increase the charging rate of a number of replacement batteries 114. This can help ensure that more fully charged replacement batteries 114 will be available at the battery exchange station 134 to satisfy the demand. In some embodiments, adjusting the one or more battery policies includes decreasing a charge rate of at least one replacement battery 114 at a battery service station 130. For example, when demand for replacement batteries 114 at a battery exchange station 134 is low, it may be advantageous to decrease the charging rate of those batteries in order to conserve energy and/or save money.

In some embodiments, adjusting the one or more battery policies includes increasing or decreasing (416) a charge rate of the battery of at least one of the electric vehicles coupled to the electric vehicle network at a battery service station. For example, if the control center system 112 predicts that there will be a high demand for a particular battery charge station 132, the control center system 112 may instruct the charge station 132 to increase the charging rate of the vehicles that are currently being charged, in order to free up charge spots for other vehicles. In some embodiments, adjusting the one or more battery policies includes decreasing a charging rate of the vehicles that are currently being charged, for example, in order to conserve energy and/or save money when demand for the charge spots is low.

In some embodiments, adjusting the one or more battery policies includes recommending (418) an alternate battery service station to a user of a respective electric vehicle. For instance, in some cases, a user 110 of a vehicle 102 may have selected a respective battery service station 130 to visit in order to charge or exchange a battery 104. Alternatively, the control center system 112 predicts that a user 110 is likely to visit a respective battery service station 130. However, the control center system 112 may also determine that the selected (or predicted) battery service station 130 will experience a high demand at the likely arrival time of the vehicle 102. Thus, in some embodiments, the control center system 112 will recommend an alternative battery service station 130 to a user. Thus, the control center system 112 can balance the demand between various charge stations 132 and exchange stations 134 by recommending that some vehicles use service stations 130 that are in lower demand.

In some embodiments, the control center system 112 recommends that a user of a vehicle visit a battery exchange station 134 instead of a battery charge station 132. Charging the battery 104 of an electric vehicle 102 takes significantly longer than exchanging a battery 104 at a battery exchange station 134. Thus, the control center system 112 may attempt to shift the relative demand toward battery exchange stations 134 in order to more quickly reduce the number of vehicles requiring additional battery charge.

In some embodiments, the control center system 112 adjusts the one or more battery policies by changing a number of available replacement batteries at one or more of the battery exchange stations 130. For example, if the control center system 112 predicts a high demand for replacement batteries 114 at a respective battery exchange station 134, the control center system 112 may cause additional replacement batteries 114 to be delivered to that battery exchange station. In some embodiments, the additional replacement batteries 114 are delivered from other battery exchange station(s) 134 that are not subject to (or are not predicted to be subject to) as such a high of a demand.

In some embodiments, the control center system 112 adjusts (412) the one or more battery policies in response to the comparison between the demand and the supply of battery services at the one or more battery service stations. For example, in some embodiments, the control center system 112 determines that demand outstrips supply at one or more battery service stations (or within a larger geographic area), and adjusts a battery policy in order to balance the supply and demand. Such adjustments can help reduce and/or prevent congestion within an electric vehicle network 100, and can help a service provider to better balance the demands of the electric vehicle network 100. Particular methods of adjusting battery policies are discussed in greater detail above with respect to steps (412)-(418).

FIG. 5 is a flow diagram of a method 500 for managing an electric vehicle network, according to some embodiments. In particular, the method 500 allows an electric vehicle network service provider to adjust one or more battery policies based on predicted demand of the electric vehicle network infrastructure, including demand for services provided at battery service stations 130 within one or more geographic areas. In other words, instead of determining a specific battery service station that a vehicle is likely to use, the control center system 112 may determine a region or area in which a vehicle is likely to require a charge or battery exchange. This method may be advantageous where it is difficult or impossible to determine with sufficient accuracy the specific battery service station 130 that a user is likely to visit. Also, it may be preferable for a service provider to visualize, analyze, or interpret demand data for entire geographic areas (usually encompassing multiple battery services stations), rather than for individual battery service stations.

In some embodiments, the method 500 is performed at the control center system 112. The control center system 112 receives (502) battery status data 41 and location data 42 from each of a plurality of electric vehicles. Step (502) is similar to step (402) described above with reference to FIG. 4, and the various embodiments and examples described above apply by analogy where applicable to step (502).

The control center system 112 identifies (504) a final destination 43 for each of the electric vehicles. Step (504) is similar to step (404) described above with reference to FIG. 4, and the various embodiments and examples described above apply by analogy where applicable to step (504).

The control center system 112, or a vehicle's navigation system, identifies (506) a likely battery service location 45 (e.g., a geographic location rather than a specific battery service station 130) and service location arrival time 46. In some embodiments, the determination of the likely battery service location 45 and arrival time 46 is based at least partially on the location data 42, the final destination 43, and the battery status data 41 for each of the electric vehicles 102. For example, because the control center system 112 has the current location 42, the final destination 43 (either selected by a user or predicted by the control center system 112, as described above), and the battery status 41 of a respective electric vehicle 102, the control center can determine a likely battery service location 45 where the vehicle is likely to seek battery service, such as battery charging or battery exchange. Furthermore, in various embodiments, the location identified as the likely charging location 45 for a respective vehicle 102 may be at any geographic resolution. For example, the location may be a specific location (e.g., a location corresponding to a single latitude and longitude coordinate), or a wider geographic region or area (e.g., a block, a town, or a city).

The control center system 112 predicts (508) demand at one or more geographic areas. In some embodiments, the prediction is based at least partially on the likely battery service location 45 and service location arrival time 46 for each respective electric vehicle. For example, and as described above, the control center system 112 determines a likely battery service location 45 and arrival time 46 for each of a plurality of vehicles 102. Based on this data, the control center system 112 determines a certain number of the plurality of vehicles that are likely to visit a particular location at (or around) a given time seeking battery services. In some embodiments, the demand for battery services at a respective location is represented by a number of vehicles (e.g., Nₜ₁₋ₜ₂) requiring service at the respective location within a certain time window (t1-t2). In some embodiments, the demand is represented by an amount of energy (e.g.,

$${Σ}_{i}^{{N}_{t 1 - t 2}} {E}_{EV - est ( t 1 - t 2 )}^{i} )$$

required by a set of vehicles that are likely to visit the respective location within a certain time window. Prediction (508) of demand is similar to step (408) described above with reference to FIG. 4, and the various embodiments and examples described above apply by analogy where applicable to step (508).

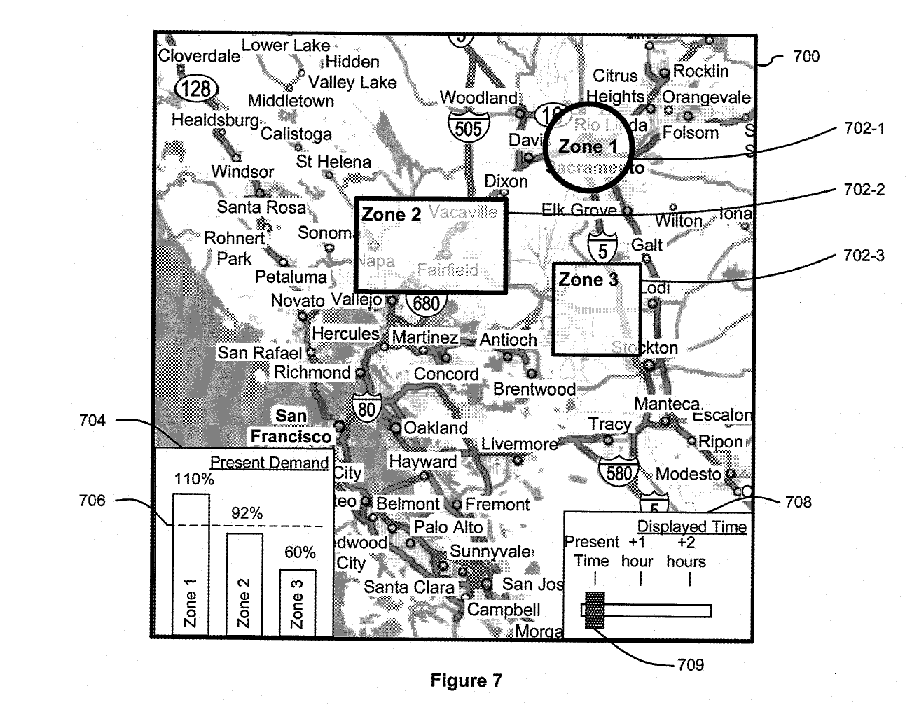

The size (and location) of the geographic areas for which demand is predicted (508) can vary depending on many factors. Criteria for determining the sizes and locations of geographic areas are described in greater detail below with reference to FIG. 7.

In some embodiments, the control center system 112 determines (509) a supply of battery services in the one or more geographic areas. In some embodiments, the control center system 112 compares (510) the demand in the one or more geographic areas and the supply of battery services in the one or more geographic areas.

Determining a supply of battery services within a geographic area and comparing the supply and demand for battery services are described in greater detail above with respect to steps (420) and (422) in FIG. 4.

In some embodiments, the control center system 112 determines (512) whether to adjust one or more battery policies responsive to the predicted demand. In some embodiments, battery policies are adjusted to help satisfy battery charging and battery exchange demands for electric vehicles 102 of the electric vehicle network 100. In some embodiments, battery policies are adjusted in order to alleviate a high demand at a respective battery service station 130, or a predicted congestion point in the electric vehicle network 100. Battery policies include, but are not limited to: charging rates of replacement batteries 114; charging rates of batteries 104 in vehicles 102 that are currently plugged into the electric vehicle network 100; a number of replacement batteries 114; reservations of services at battery service stations 130 (e.g., battery exchange lanes or charge spots); and recommendations of battery service stations 130 made by the control center system 112.

In some embodiments, the control center system 112 adjusts (514) the one or more battery policies based on the demand at the one or more battery service stations 130. In some embodiments, adjusting the battery policies includes increasing a charge rate of at least one replacement battery 114 coupled to the power grid of the electric vehicle network 100 at a battery service station 130. For example, if the control center system 112 predicts that there will be a high demand for replacement batteries 114 within a particular geographic area, the control center system 112 may instruct one or more exchange stations 134 within that geographic area to increase the charging rate of a number of replacement batteries 114. This can help ensure that more fully charged replacement batteries 114 will be available within the geographic area to satisfy the demand. In some embodiments, adjusting the one or more battery policies includes decreasing a charge rate of at least one replacement battery 114 within a geographic area. For example, when demand for replacement batteries 114 within a geographic area is low, it may be advantageous to decrease the charging rate of those batteries in order to conserve energy and/or save money.

In some embodiments, adjusting the one or more battery policies includes increasing or decreasing a charge rate of at least one of the electric vehicles coupled to the electric vehicle network within a geographic area. For example, if the control center system 112 predicts that there will be a high demand for battery charging within a geographic area, the control center system 112 may instruct one or more charge stations 132 within a geographic area to increase the charging rate of the vehicles that are currently being charged, in order to free up charge spots for other vehicles. In some embodiments, adjusting the one or more battery policies includes decreasing a charging rate of the vehicles that are currently being charged, for example, in order to conserve energy and/or save money when demand for charge spots is low.

In some embodiments, adjusting the one or more battery policies includes recommending that a user 110 of a vehicle visit a battery service station 130 in an alternate geographic area. For instance, in some cases, a user 110 of a vehicle 102 has selected a respective battery service station 130 within a geographic area where demand for battery services is high. Therefore, in some embodiments, the control center system 112 recommends that the user 110 of a vehicle 102 visit a battery service station 130 in an alternate geographic area. Accordingly, the control center system 112 can balance the demand between various geographic areas by recommending that some vehicles use battery service stations 130 in lower demand areas.

In some embodiments, the control center system 112 adjusts (514) the one or more battery policies by changing a number of available replacement batteries at one or more of the battery service stations within a respective geographic area. For example, if the control center system 112 predicts a high demand for replacement batteries 114 at the battery exchange stations 134 within a geographic area, the control center system 112 may cause additional replacement batteries 114 to be delivered to the respective battery exchange station 134. In some embodiments, the additional replacement batteries 114 are delivered from battery exchange station(s) in geographic areas that are not experiencing (or are not predicted to experience) as such a high of a demand. As described above with reference to FIG. 4, in some embodiments, the control center system 112 adjusts (514) the one or more battery policies based on the comparison (510) between the supply and demand of battery services in a geographic area.

In some embodiments, certain portions of the methods described above are performed by the vehicle 102, and in particular, by one or more components of the “vehicle operating system.” For example, the vehicle navigation system of the positioning system 106 may determine the likely battery service station 45 and vehicle arrival time 46 at the likely battery services station. In some embodiments, when the vehicle 102 performs any of the above mentioned steps, the vehicle 102 (e.g., using the communication interface(s) 204) sends related information to the control center system 112 for further processing, storage, and/or analysis.

The following are some example of the graphical representations of predicted demand.

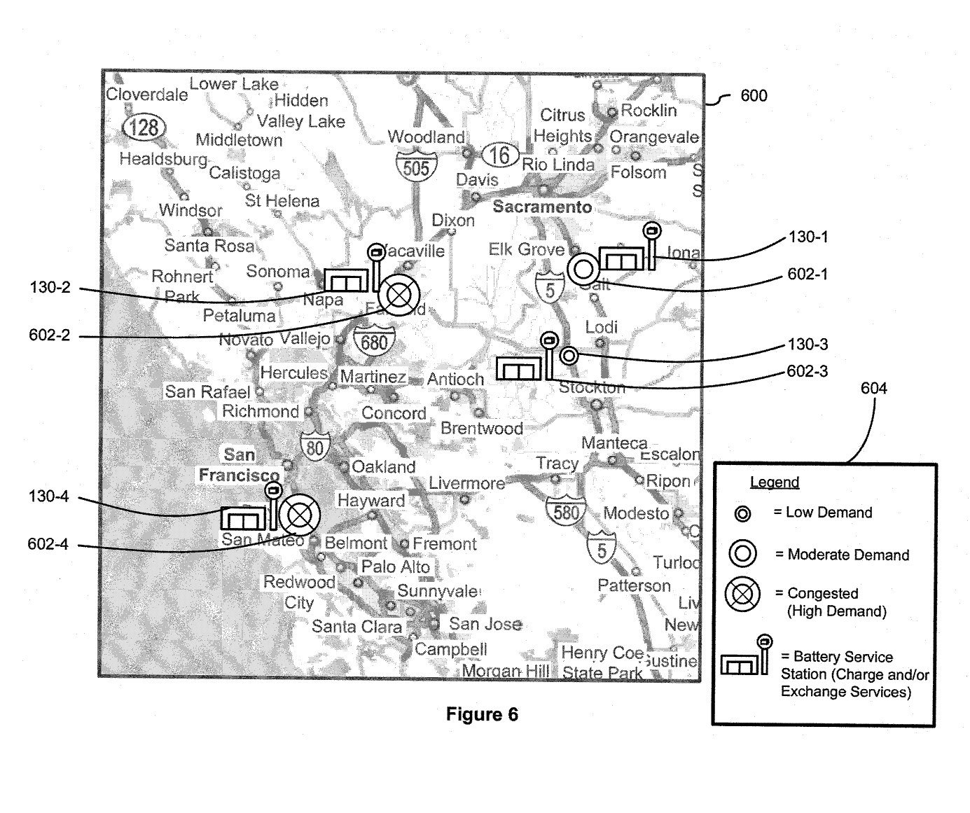

In order to facilitate visualization of the predicted demand at the battery service stations 130, predicted demand data may be displayed in conjunction with a map on a display device. FIG. 6 illustrates a map 600 for displaying demand data, according to some embodiments. Maps graphically displaying demand data (50) may be displayed to individuals who monitor or operate the electric vehicle network, such as a user of the control center system 112. In some embodiments, the maps are displayed on display devices at the control center system 112. Maps can be generated and displayed by one or more computer systems or computer devices, such as the control center system 112, described in greater detail with reference to FIG. 3. In some embodiments, the maps are generated and displayed by a map module 324 of the control center system 112.

Furthermore, in some embodiments, maps are generated using the demand data stored in the demand data database 332 and/or the battery service station data (including battery service supply data) in the battery service station database 330 of the control center system 112. In some embodiments, maps are displayed on the display device 306 of the control center system 112.

In some embodiments, the map 600 includes representations of one or more battery service stations 130-n, as well as indicators 602-n of the relative demand at the battery service stations 130-n. As shown in the legend 604, the map 600 indicates relative demand at a respective battery service station 130 by displaying circles at certain points on the map 600, where a larger circle indicates a larger demand value. In some embodiments, when congestion is predicted at a respective battery service station, such as service station 130-1, the demand indicator further indicates that a threshold for predicting congestion has been reached. In the map 600, a congestion point is indicated by a double circle enclosing an “X.” In some embodiments, this threshold corresponds to a determination (e.g., from the comparing steps (420) and (510), described above) that the demand for battery services outstrips supply at a particular location.

FIG. 7 illustrates a map displaying demand data for geographic areas, rather than demand data for respective battery service stations. Accordingly map 700 identifies a number of zones/regions 702-n within a larger geographic area. The zones 702-n may contain one or more battery service stations 130, and are defined by any boundary. In some embodiments, a zone/region 702-n is coextensive with the boundaries of a city, town, or county, or other predefined area. In some embodiments, a zone 702-n is a predetermined area near an entrance or exit to a highway. In some embodiments, zones 702-n are arbitrarily defined areas. In some embodiments, zones 702-n can be of various different sizes, or all the same size. For example, zones encompassing geographic area with a high volume of vehicle traffic (e.g., in or around a large city) may be smaller than zones encompassing areas with less traffic. For example, zones are sometimes sized based on the driving ranges of the vehicles 102 in the electric vehicle network 100. In some embodiments, zones 702-n are sized so that electric vehicles 102 with a fully charged battery can travel through the entire zone without requiring battery services. In some embodiments, the zones 702-n are sized so that electric vehicles 102 with only a quarter of a full battery charge can travel through the entire zone without requiring battery services. Of course, the ranges of different vehicles 102 will vary considerably. Thus, the ranges of the vehicles are sometimes calculated average ranges for a population of vehicles.

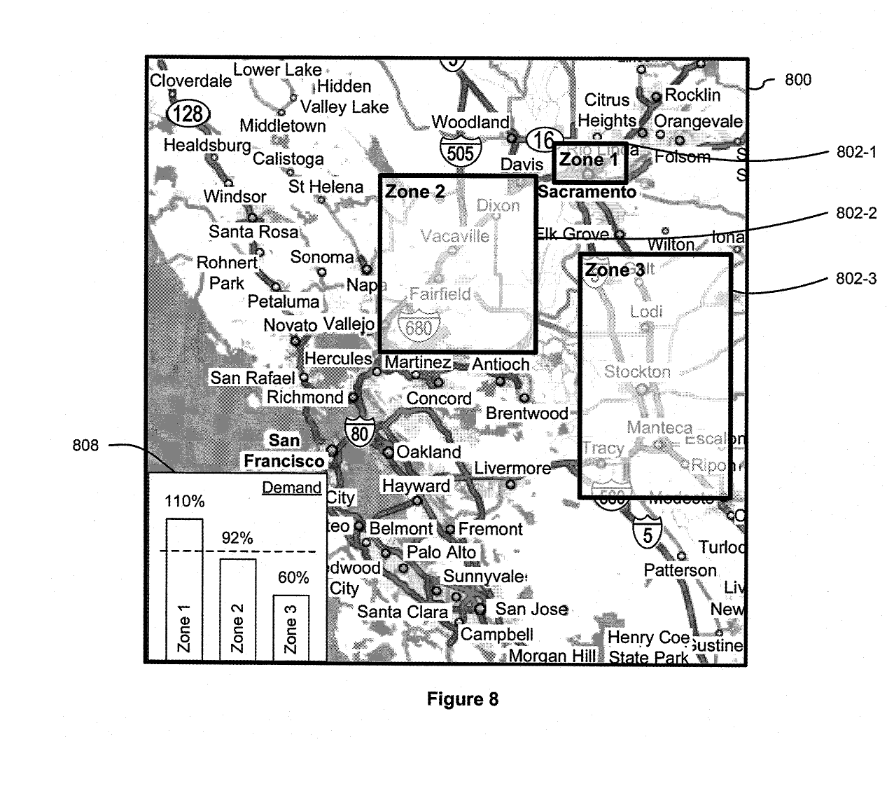

FIG. 8 illustrates a map 800 displaying demand data for geographic areas where the zone 802-1 that encompasses a high-volume traffic area (Sacramento, Calif.) is smaller than the zones 802-2, 802-3 encompassing low-volume traffic areas that do not incorporate large metropolitan areas.

Returning to FIG. 7, map 700 illustrates a zone 702-1 (labeled as Zone 1), zone 702-2 (labeled as Zone 2), and zone 702-3 (labeled as Zone 3). Map 700 also includes a graph 704 that shows the present demand for each of the zones. Graph 704 is a bar graph where the height of the bar represents the demand for battery services within a respective zone, although one of skill in the art will recognize that other graphs or graphical representations may be used. Each bar (corresponding to a respective zone) in the graph 704 also includes a congestion threshold indicator 706, showing the point at which that zone will be considered to be congested. Predicting congestion is described in greater detail above with respect to FIG. 6. FIG. 8 illustrates a graph 808 similar to the graph 704.

Map 700 also illustrates a time selector 708, depicted as a sliding graphical element. A user 110 may manipulate a slider 709 in order to change the time of the demand values that are displayed on the map 700. As shown, the map illustrates the present demand. However, a user may move the slider 709 to cause the map to update the demand values for the selected time. As illustrated, the time selector 708 uses one-hour increments, but other time increments may also be employed. Further, the selector need not be limited to discrete time increments. In other words, in some embodiments, the time selector 709 allows a user 110 to select any time or time increment in between the displayed increments, such as fifteen minute increments.

As noted above, the maps 600, 700, 800 are sometimes displayed to an individual at the service provider 112 who manages aspects of the electric vehicle network 100. The operator may use the maps to help determine whether and how to adjust battery policies, as well as what battery policies to adjust. Furthermore, while demand data (e.g., in the predicted demand data database 332) is sometimes displayed on the maps 600, 700, 800, this is not necessary in all embodiments of the present invention. For example, in some embodiments, demand data can be displayed to a user in tabular or textual form. Furthermore, in some embodiments, demand data is not displayed or provided to an individual at all, but rather is simply used by the control center system 112 so that the control center system 112 (e.g., with the battery policy module 323) can determine whether and how to adjust battery policies in response to predicted demand values.

While the maps shown in FIGS. 6-8 show relative demand with particular types of graphical indicators, one of skill in the art will recognize that other representations or graphical depictions may be used in some embodiments. For instance, in some embodiments, relative or absolute demand data may be indicated with shapes, numbers, colors, words, and/or any other graphical or textual element (including differently sized or emphasized graphical elements to indicate relative demand between battery service stations or areas).

The following are some examples of the flexible demand load management.

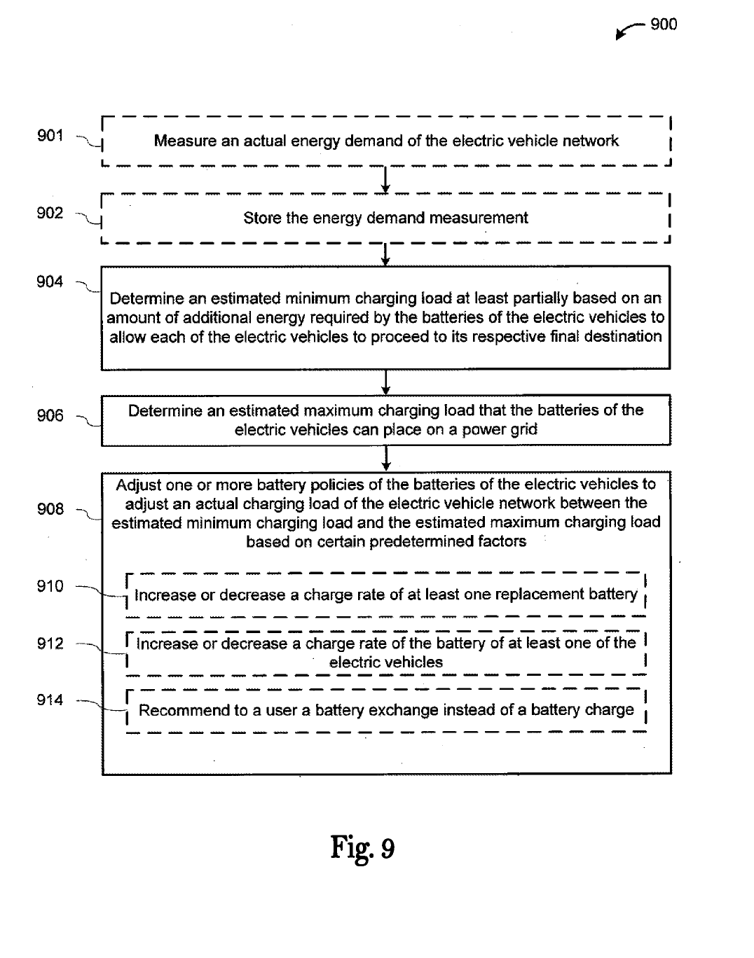

FIG. 9 is a flow diagram 900 of a method for managing an electric vehicle network, according to some embodiments. In particular, the method 900 allows a service provider of an electric vehicle network 100 to adjust its power draw (e.g., the electrical load caused by charging the batteries of the electric vehicle network 100) from a power grid based on certain predictions about the energy requirements of the vehicles 102 and/or replacement batteries 114 within the network. For example, as described above, the control center system 112 of an electric vehicle network service provider sometimes uses information for each vehicle and/or battery such as the current location, final destination, and battery charge level to predict the demand for battery services at locations within the electric vehicle network 100. As described in greater detail below, the control center system 112 may use similar information to determine an estimated and/or predicted charging load that the electric vehicles will place on a power grid. Battery policies of the electric vehicle network can then be adjusted in various ways based on the estimated charging load. For example, battery policies are sometimes adjusted in order to minimize electricity consumption by the electric vehicle network when electricity is expensive, and maximize electricity consumption (e.g., for storage and later use) when electricity is inexpensive.

Returning to FIG. 9, the control center system 112 determines (904) an estimated minimum charging load at least partially based on an amount of additional energy required by the batteries of the electric vehicles to allow each of the electric vehicles i to proceed to its respective final destination 43. For example, some vehicles 102 currently being charged, or vehicles that are travelling, do not have a sufficient charge to reach their final destinations 43, and will require some additional charge.

In some embodiments, the minimum charging load is a rate of energy consumption by the batteries of the electric vehicle network 100 from the power grid (e.g., the rate of energy consumption caused by their charging, sometimes measured in kilowatts (kW)). This rate, in turn, is calculated or determined by the control center system 112, and is based on a minimum energy requirement of each vehicle (e.g., the quantity of additional energy required by a battery, sometimes measured in kilowatt-hours (kW-h)). In other words, the minimum charging load (E_{Net-min}) is sometimes represented as a charging rate that would be experienced by the electric vehicle network if each vehicle were to receive its minimum energy requirement to reach its known or estimated final destination. As described in greater detail below, the minimum charging load may be based on predictions of respective vehicle's energy demands, and can be projected into the future in order to anticipate upcoming charging demands of the electric vehicle network 100.

In some embodiments, the minimum charging load may be represented not as a rate, as described above, but rather as a quantity of energy. In these cases, the minimum charging load directly represents the estimated quantity of energy (e.g., measured in kW-h) required by each vehicle to satisfy its minimum energy requirements. For clarity, the minimum charging load is described herein as a charging rate. However, one of skill in the art will understand that the disclosed concepts, including the minimum and maximum charging loads, apply by analogy to measurements of energy quantities (e.g., kW-h), energy transfer rate (e.g., kW), or any other suitable metric.

As noted above, in some embodiments, the minimum charging load represents an estimated overall charging load that will likely be placed on a power grid in order to charge the batteries of each of the electric vehicles 102 to its minimum charge level. In some embodiments, this minimum charge level is determined based on the final destination 43, a current location 42, and a current battery status (e.g., charge level) 41 of each battery of the respective electric vehicles 102. As described above, other factors are also sometimes used, including speed and/or current traffic information. In other words, the control center system 112 determines for each vehicle i the amount of energy (e.g., in kW-h) that the vehicle requires, in addition to its current battery charge level, to reach its final destination 43. For example, if a vehicle 102 has enough charge to travel 20 miles, and is 50 miles away from its final destination 43, the vehicle 102 will require approximately 30 more miles worth of energy in order to reach the final destination.

While energy may be measured or represented in various units, such as kW-h, Joules, British thermal units, etc., it is sometimes referred to herein in terms of the mileage value of energy. One of skill in the art will recognize that due to differences in size, weight, efficiency, etc., different vehicles will be able to travel different distances on a given amount of energy. The final destination 43 of a respective vehicle 102 can be a predicted final destination or an intended destination that is selected by a user 110 of an electric vehicle 102. Final destinations 43, including predicted and intended destinations, are discussed in greater detail above with respect to FIGS. 4-5.

In some embodiments, the amount of additional energy required by the batteries 104 of the electric vehicles 102 is associated with a time component indicating when the additional energy will be required. For instance, as described in greater detail above, the control center system 112 may determine that a vehicle 102 is likely to require 30 more miles worth of energy at a time 20 minutes in the future. Thus, it is likely that the vehicle will arrive at a battery charge station 132 in 20 minutes to receive the additional 30 miles worth of energy. In some embodiments, the control center system 112 takes the time at which the energy will be required into consideration when determining (904) the estimated minimum charging load. Thus, the control center system 112 is able to determine both the amount of charge that a vehicle 102 will require, and the time at which the vehicle 102 is likely to be charged. Using this data, the control center system 112 may determine estimated minimum charging loads, based on the additional energy requirements of the vehicles, over a future time window. In some embodiments, the time window is 1 hour into the future. In some embodiments, the time window is 1 day into the future, or any other suitable time period. Because estimated charging loads may be predicted for times in the future (sometimes themselves being based on predicted final destinations of respective vehicles), the accuracy of the future estimated minimum charging loads will decrease the further out in time that the predictions are made. For example, predictions of a user's final destination 43 a full day in advance may be less accurate than predictions about that user's final destinations 43 one hour in advance.

In some embodiments, the control center system 112 uses historical charging demand data in order to better predict future minimum charging loads. In some embodiments, before the control center system 112 adjusts the one or more battery policies, the control center system 112 measures (901) an actual energy demand of the electric vehicle network over a predetermined time window. In some embodiments, the energy demand corresponds to the actual amount of energy used by the electric vehicle network 100 over the predetermined time window (e.g., the amount of energy used within a particular time span of any suitable duration, such as minutes, hours, days, etc.). In some embodiments, the energy demand corresponds to the aggregated individual energy usage of each of (or a subset of) the vehicles 102 of the electric vehicle network 100. In some embodiments, the control center system 112 stores (902) the historical data in order to extract historical trends in energy usage. In some embodiments, the control center system 112 stores the actual energy demand to be used later as historical data in the predicted demand database 332 (FIG. 3). In some embodiments, the historical actual energy demand data is used to predict the energy demand of the electric vehicle network 100, and thus predict the estimated minimum charging load for future time windows.

Historical data can be analyzed at a vehicle level, or at a network level. For example, in some embodiments, the control center system 112 may determine that particular users 110 of vehicles 102 have predictable driving habits, and therefore predictable charging behavior. The energy demands and charging behavior of individual users 110 can be aggregated in order to determine overall, network-level energy demand predictions. In some embodiments, the control center system 112 may evaluate the actual energy demand of the overall electric vehicle network 100, and thus make energy demand predictions directly from the network-level demand data. In some embodiments, the control center system 112 uses one or more prediction methods to identify the final destination for a respective electric vehicle. See, e.g., U.S. patent application Ser. No. 12/560,337, which is hereby incorporated by reference in its entirety. In some embodiments, the control center system 112 identifies a final destination for a respective electric vehicle based on historical travel data for a respective user 110. The control center system 112 uses the historical travel data in order to aid in predicting final destinations 43, and ultimately in predicting charging demands.

Returning to step (904), in some embodiments, the control center system 112 combines the additional energy requirements of a number of individual vehicles 102 to determine the overall additional energy requirements of the electric vehicle network 100. In some embodiments, the control center system 112 increases the amount of additional energy required by the batteries by a predetermined safety factor. In other words, because the amount of additional energy required by any individual vehicle may be determined from factors that may have lower confidence levels, the control center system 112 accounts for variances by including a safety margin. In some embodiments, the calculated amount of additional energy is increased by 10-20%. Furthermore, this safety factor or margin may be applied at an individual vehicle level, so that if it is determined for a respective electric vehicle 102, that 30 miles worth of additional energy is required, the control center system determines that the vehicle 102 must receive at least 40 miles worth of additional energy in order to safely reach its final destination. In some embodiments, the particular safety factor or margin is determined at least in part on an individual's driving history or habits. In some embodiments, the safety factor may be applied to the amount of additional energy required by the overall electrical vehicle network 100, rather than that of the individual vehicles 102. For example, if it is estimated that, in aggregate, the electric vehicles 102 in the electric vehicle network 100 require a minimum of ten thousand Kilowatt-hours of additional energy, the control center system 112 may increase the requirement to twelve thousand Kilowatt-hours.

In some embodiments, the estimated minimum charging load is a sum of estimated minimum individual charging loads placed on the power grid by each respective electric vehicle. Thus, the control center system 112 may aggregate expected charging loads for individual vehicles 102 to determine an overall minimum charging load of the electric vehicle network 100. For example, the control center system 112 may predict expected minimum charging loads for individual vehicles 102 (e.g., based on the additional amount of energy required by each of those vehicles to reach their respective final destination), and sum those values to determine the overall estimated minimum charging load of the electric vehicle network 100.

In some embodiments, some or all of the electric vehicles 102 of the electric vehicle network 100 have an associated minimum battery charge level that is set by one or more service agreements with an owner or an operator of the respective electric vehicle. In some embodiments, this minimum battery charge level represents the lowest charge level that a user 110 of a respective electric vehicle 102 is willing to accept. For example, a user 110 of an electric vehicle 102 may agree that unless the user 110 has specifically requested a full battery charge, the electric vehicle network service provider may adjust charging rates of the battery 104 (and the overall energy stored in the battery 104) as long as the vehicle remains at least 80% charged at all times. In some embodiments, a user 110 may identify to a control center system 112 (or to the vehicle 102, which can communicate with the control center system 112) an intended final destination 43. The control center system 112 may then override the agreed upon minimum battery charge level of that user's vehicle based on the intended final destination. For example, if a user 110 identifies an intended final destination 43 that requires more than a full battery charge, the control center system 112 may ensure that the user's vehicle is fully charged. If, however, a user 110 identifies an intended final destination that requires only a smaller amount of charge, the control center system 112 may ignore the agreed upon minimum charge level based on the lower energy requirements for that trip. In some embodiments, when overriding a minimum charge level, the control center system 112 also takes into account the energy required for a return trip. Thus, if a user 110 identifies as an intended destination 43 a grocery store that is 5 miles from the user's home, the control center system 112 may ensure that a vehicle has enough charge to travel 10 miles (sometimes including an additional safety factor, as described above).

As described in more detail below, the control center system 112 sometimes makes use of excess battery capacity (e.g., capacity of a battery 104 above its minimum charge level) as energy storage, and can charge or discharge those batteries at different times in order to optimize the electric vehicle network. In some embodiments, discharging is permitted so long as the battery 104 always contains at least the associated minimum battery charge level. Establishing a minimum battery charge level, as described above, ensures that a battery 104 will always have at least some charge so that the vehicle can be used without advance notice, or in an emergency.

Sometimes, users 110 of vehicles do not require that their vehicles are always charged for immediate use. Thus, in some embodiments, service agreements with owners or operators of electric vehicles do not include minimum battery charge levels. For example, some service agreements may state that the electric vehicle network provider may adjust the overall charge level of those electric vehicles to any level, unless the owner or operator of the vehicle has specifically identified a required charge level, or selected an intended final destination. In some embodiments, service agreements where there is no minimum battery charge level are less expensive than service agreements where minimum battery charge levels are established. Further, service agreements where minimum battery charge levels are higher (e.g., 90%) may be more expensive than those where minimum battery charge levels are lower (e.g., 40%).

Returning to FIG. 9, the control center system 112 determines (906) an estimated maximum charging load that the batteries of the electric vehicles can place on a power grid. In some embodiments, the estimated maximum charging load represents a rate of energy consumption if substantially all of the electric vehicles 102 likely to be coupled to the power grid at a certain time were to be simultaneously charged at a maximum rate. Like the estimated minimum charging load, the estimated maximum charging load may alternatively represent a maximum quantity (e.g., in kw-h) of energy that the batteries (or other storage components) of an electric vehicle network 100 can store at any given time. Estimated maximum charging loads may be determined for particular subsets of the electric vehicle network 100. For example, in some embodiments, maximum charging loads are determined individually per region, city, land area, utility provider, power grid/transmission boundary, etc.

In some embodiments, the electric vehicle network 100 includes a plurality of replacement batteries 114 configured to be charged from the power grid. In some embodiments, the estimated maximum charging load represents a rate of energy consumption from the power grid if both the batteries 104 of the electric vehicles 102 and the replacement batteries 114 were to be simultaneously charged at a maximum rate.

In some embodiments, the estimated maximum charging load takes into account the number of batteries that are likely to be coupled to the power grid at a given time. Specifically, batteries that are not or will not be coupled to the power grid should not be considered in the estimation of the maximum charging load, as those batteries cannot receive any electrical energy. For example, if the control center system 112 determines or predicts that a certain subset of vehicles are currently traveling, and/or are not likely to be charging at a certain time (e.g., because the vehicle is historically not coupled to the power grid at that time of day, or because it is already fully charged), then those vehicles are not included in the estimated maximum charging load. Further, if a battery service station 130 has more replacement batteries 114 than it can charge at any one time, those additional replacement batteries 114 are not included in the estimated maximum charging load. Thus, the estimated maximum charging load may be limited to those batteries that are currently coupled to the power grid, or that are predicted to be coupled to the power grid within that time period.

In some embodiments, the electric vehicle network 100 also includes other types of energy storage in addition to the vehicle batteries 104 and the replacement batteries 114. For example, energy storage components such as storage batteries, mechanical flywheels, fuel cells, and the like may also be included.

In some embodiments, the estimated maximum charging load also accounts for one or more capacity constraints of the power grid or the components of the electric vehicle network 100. In some embodiments, battery charging equipment (including power transmission wiring, switchgear, transformers, etc.) in the electric vehicle network 100 has electrical load limits that cannot safely be exceeded. Thus, the estimated maximum charging load may account for these limits when determining the maximum load that can be placed on the power grid by the electric vehicle network 100.

One of skill in the art will recognize that the actual charging load (E_{Net-act}) of the electric vehicle network (including, for example, electric vehicle batteries 104, replacement batteries 114, etc.) can be varied by altering the charging rates of the batteries that are connected to the power grid. Thus, the actual charging load that the electric vehicles place on the power grid takes into account both the number of batteries that are being charged, as well as the rate at which those batteries are being charged. As described in more detail below, the battery control center 112 may adjust the charging rates of the batteries of the electric vehicle network 100 so that the actual charging load of the batteries is between the estimated maximum charging load E_{Net-max} and the estimated minimum charging load E_{Net-min}.

Returning to FIG. 9, the control center system 112 adjusts (step 908) one or more battery policies of the batteries of the electric vehicle network 100 so as to adjust an actual charging load E_{Net-act} of the electric vehicle network between the estimated minimum charging load E_{Net-min} and the estimated maximum charging load E_{Net-max} based on certain predetermined factors. The actual charging load E_{Net-act} corresponds to the actual rate of energy consumption by the batteries that are coupled to the power grid at a current time. In some embodiments, the batteries include batteries 104 in electric vehicles 102, and replacement batteries 114. In some embodiments, the actual charging load also includes the charging load caused by other energy storage components, as described above.

Because the control center system 112 of a service provider has determined estimated maximum and minimum charging loads for the electric vehicle network, the service provider may choose to adjust (step 908) the battery policies (thus adjusting the overall charging load of all the batteries coupled to the power grid) based on a number of different possible factors. As described above, the estimated maximum charging load E_{Net-max} represents an upper limit on the electrical energy consumption rate of the electric vehicle network 100, and the estimated minimum charging load E_{Net-min} represents a lower limit on the electrical energy consumption rate of the electrical vehicle network 100. Thus, the control center system 112 adjusts the actual charging rate E_{Net-act} of the electric vehicle network to be between these two limits (i.e., E_{Net-min}<E_{Net-act}<E_{Net-max}). For example, if the estimated maximum charging load is ten thousand kW, and the estimated minimum charging load is eight thousand kW, the control center system 112 will adjust battery charging rates so that the actual charging load is somewhere between those two values, such as nine thousand kW, based on the factors presented below.

Sometimes, the minimum additional energy required by the electric vehicle network 100 is zero, or even negative. This may occur when the energy storage components of an electric vehicle network 100 (e.g., batteries 104 in electric vehicles 102, replacement batteries 114, etc.) have an overall surplus of energy above the minimum required energy required for each vehicle to reach its final destination. In other words, it may be that each vehicle in the electric vehicle network has more than enough charge to reach its final destination. Thus, the minimum additional amount of energy required by the electric vehicle network is negative, because each vehicle has a surplus of energy. Typically, vehicles will not all have a surplus of energy over and above their minimum requirements at any given time. However, the electric vehicle network 100 can have a negative overall additional energy requirement (i.e., an energy surplus) when the sum of the additional energy requirements of each vehicle 102 (including both positive and negative additional energy requirements) is negative. In some embodiments, the electric vehicle network will have a negative additional energy requirement when the electric vehicle network 100 has enough energy stored in replacement batteries 114 (or other energy storage components) to accommodate the minimum requirements of the electric vehicles 102 that do not have enough charge to reach their final destinations. As discussed in greater detail below, when the electric vehicle network 100 has a negative minimum additional energy requirement (i.e., a surplus of energy), the network may discharge energy to the power grid.

In some embodiments, the control center system 112 adjusts (908) one or more battery policies based on certain factors, including the price of energy from the power grid, known upcoming charging demand, predictions of upcoming charging demand, historical charging data, specific requests from power providers, times of minimum or maximum energy use by other entities, air pollution considerations (such as air quality indices or ozone levels), greenhouse gas emission rates or quantities, etc.

Often, a service provider of an electric vehicle network 100 will act as an intermediary between the users 110 of electric vehicles 102, such that the service provider purchases electricity from a utility provider, and subsequently sells the electricity to the users 110 of the electric vehicles 102 as part of an energy purchase contract or subscription plan. Further, the price of electricity from utility providers varies based on a number of different factors, such as the time of day. In order to reduce overall power costs, the service provider of the electric vehicle network 110 sometimes seeks to minimize energy consumption from the power grid when electricity is expensive, and maximize energy consumption when electricity is inexpensive. Specifically, in some embodiments, the control center system 112 uses the estimated minimum and maximum charging loads of the electric vehicle network 100, in conjunction with price data for electrical power to determine when it is cost efficient to maintain the actual charging load at (or near) the minimum charge load, or at (or near) the maximum charge load. For example, when the price of electricity is low, the control center system 112 may increase the charging load (e.g., by increasing the charge rates of batteries coupled to the power grid) in order to take advantage of the cheap electricity. In contrast, when the price of electricity is high, the control center system 112 may decrease the charging load (e.g., by decreasing the charge rates of batteries coupled to the power grid) in order to reduce the amount of expensive electricity that the service provider must purchase.

As described above, the control center system 112 can adjust the instantaneous (i.e., the current) charging load of the electric vehicle network 100 based on instantaneous estimated maximum and minimum charging loads, as well as the instantaneous pricing of electricity. Furthermore, because the control center system 112 can predict when, in the future, users 110 of electric vehicles 102 will require additional energy, and further predict how much additional energy those vehicles 102 will need, the control center system 112 can further adjust the current actual charging load of the batteries of the electric vehicle network based on its knowledge of these future charging requirements. For example, the control center system 112 at 3:00 PM may predict that a large number of vehicles will be traveling from a work location to a home location at 5:00 PM. The control center system 112 may also identify that each vehicle requires, on average, 10 miles worth of additional battery charge in order to reach their home location (including an appropriate safety margin). Thus, the control center system 112 can take this future power demand into consideration when adjusting the current charging load.

For example, if electricity is expensive between 3:00 and 5:00 PM, the control center system 112 may adjust the charging rate of the vehicles so that they receive only the minimum amount of additional energy necessary for them to each reach their final destination (e.g., an average of 10 miles worth of additional energy per vehicle). The estimated minimum charging load, in this case, ensures that each vehicle receives adequate energy to reach its final destination. If, on the other hand, electricity is inexpensive between the hours of 3:00 and 5:00 PM, the control center system 112 may increase the charging rates of the vehicles to the maximum charging rates, even if that rate would provide more stored energy than necessary for those vehicles to reach their final destinations.

FIG. 13 is a flowchart demonstrating a possible process for adjusting the actual charging rate E_{Net-act} of the vehicle network 100 according to the price of electricity and the estimated minimum (E_{Net-min}) and maximum (E_{Net-max}) charging loads of the network 100. In this example the estimated minimum (E_{Net-min}) and maximum (E_{Net-max}) charging loads of the network 100 are periodically, or intermittently, updated in step 61, as described hereinabove. For example, the estimated minimum and maximum charging loads may be updated based on the actual state and requirements of the vehicles 102, of the batteries 102 and 114, the power network 140 and/or the vehicle network 100. Next it is checked in step 62 if the network actual charging E_{Net-act} rate is greater than the minimum charging load E_{Net-min}. If it is found that the network actual charging rate is smaller than the minimum charging load, then the electrical charging current consumption rate of the network is increased in step 66. Otherwise, if it is found that the network actual charging rate is greater than the minimum charging load, then the current price of electricity is checked in step 63.

If it is found that the electricity price is currently high, then the electrical charging current consumption rate of the network is decreased in step 64. Otherwise, if it is found that the electricity price is currently not high, then it is checked in step 65 if the network actual charging E_{Net-act} rate is greater than the maximum charging load E_{Net-max}. In the event that the network actual charging rate is indeed greater than the network maximum charging load, then the control is passed to step 64 to decrease the electrical charging current consumption rate of the network. On the other hand, if the network actual charging rate is smaller than the network maximum charging load, then the control is passed to step 66 to increase the electrical charging current consumption rate of the network. After each increase/decrease (66/64) in the network electrical charging current the control is passed back to step 61 to update the minimum and maximum charging loads of the network 100.

Thus, the ability of the control center system 112 to adjust the actual charging load of the batteries in the electric vehicle network 100, coupled with the ability of the batteries to store more energy than is required to satisfy a vehicle's transportation demands, allows the control center system 112 control over a “flexible” charging load of the electric vehicle network 100. In other words, the actual charging load may be adjusted within a range below the maximum available charging load, but high enough to satisfy minimum transportation demands of each vehicle.

As described above, the control center system 112 may determine how or whether to adjust battery policies of the batteries in the electric vehicle network 100. However, in some embodiments, a utility provider (e.g., an owner or an operator of the power network 140 and/or the power generators 156) provides a requested charging profile to the electric vehicle network service provider. In some embodiments, the control center system 112 sends, to a utility provider, the estimated minimum charging load and the estimated maximum charging load, and receives from the utility provider an energy plan including preferred charging loads for a predetermined time window. By allowing the utility provider to generate a preferred load profile to the service provider, the utility can use the “flexible” charging load of the electric vehicle network to its benefit. Specifically, the utility provider can use the “flexible” load of the network 100 to help balance the demand placed on the power generators 156, and to store electricity for later use.

In some embodiments, adjusting the battery policies includes increasing or decreasing (step 910) a charge rate of at least one replacement battery 114 coupled to the power grid at a battery service station 130. In some embodiments, adjusting the battery policies includes increasing or decreasing (step 912) a charge rate of the battery of at least one of the electric vehicles 102. In some embodiments, adjusting the battery policies includes recommending an alternative battery service station to a user of a respective electric vehicle. In some embodiments, adjusting the battery policies includes increasing or decreasing a charge rate of at least one of the storage batteries 114 of the electric vehicle network 110. In some embodiments, adjusting the battery policies includes adjusting the amount of energy that a battery receives from the power grid or discharges to the power grid. In some embodiments, charge rates of batteries are constant, and the control center system 112 only changes the quantity of energy that the batteries receive. In some embodiments, adjusting the battery policies includes recommending (914) to a user a battery exchange instead of a battery charge. Further details relating to adjusting battery policies are described in greater detail above with reference to FIG. 4. Also, the described battery policy adjustments apply by analogy to other energy storage components as well.

In some embodiments, in order to facilitate analysis and/or display of the information, the estimated minimum and maximum charging load over time are each represented by a set of data points over a predefined time window. Each data point represents an energy measurement at a certain future time. In some embodiments, the energy measurements represent a rate of energy transfer (e.g., in kW). In some embodiments, energy measurements represent a quantity of energy (e.g., in kW-h). In some embodiments, at least a subset of the data points are fit to a curve function, which can then be plotted and displayed on a display device in order to facilitate visualization of the data. An operator of a control center system 112 (or at a utility provider) may view the displayed curve to aid in determining whether and how to adjust the battery policies of the electric vehicle network. In some embodiments, the control center system 112 or the utility provider automatically determines whether and how to adjust the one or more battery policies without direct operator intervention, and/or without displaying any information to a control center operator.

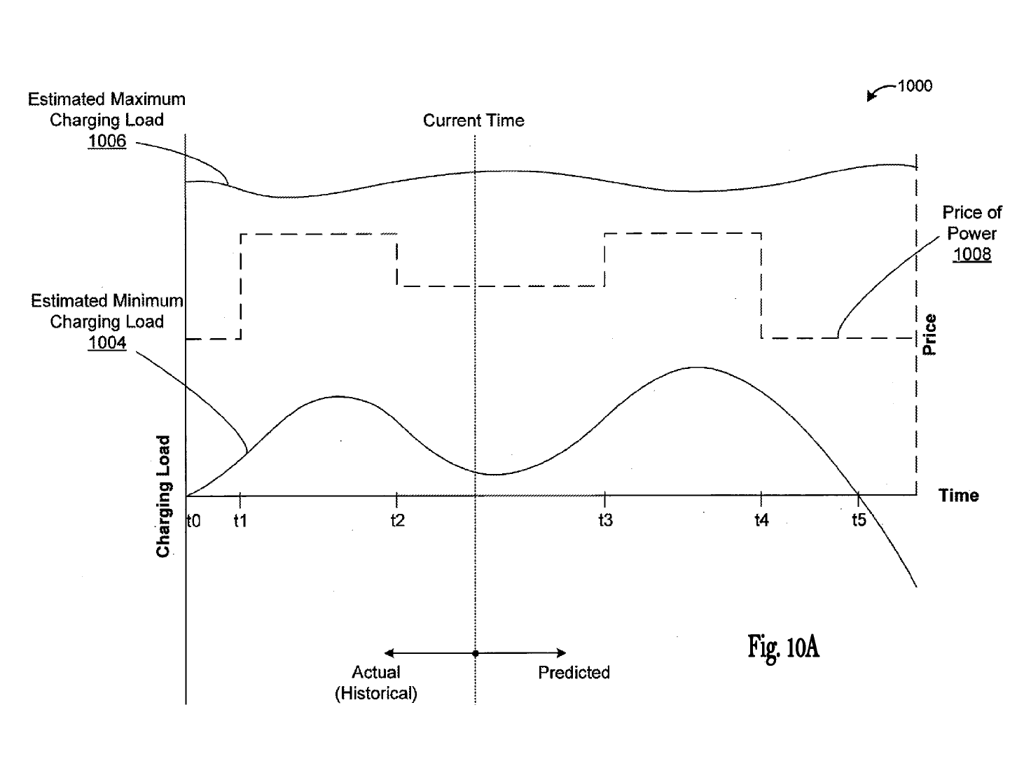

FIG. 10A illustrates a graph 1000 displaying estimated minimum and maximum charging load curves, according to some embodiments. The x-axis of the graph represents time, and the left-hand y-axis represents charging load, measured in rate of energy consumption (e.g., in kW). The right-hand y-axis represents price (e.g., in dollars). FIG. 10A illustrates one possible charging load curve for part of a typical day, for example, from 6:00 AM to 10:00 PM.

The estimated maximum charging load curve 1006 (and estimated maximum charging load curve 1012, FIG. 10B) shows the variation of the estimated maximum charging load of the electric vehicle network 100 over time. As shown in FIG. 10A, the maximum charging load is relatively stable. However, the stability of the estimated maximum charging load depends on many factors, and may be significantly different from that shown in FIG. 10A. For example, the ratio of replacement batteries 114 and energy storage components to electric vehicles 102 may have a significant impact on the stability of the curve 1006, as vehicles are not always coupled to the power grid. If there are substantially more replacement batteries 114 than there are vehicles 102 in the electric vehicle network 102, then the relative impact of the vehicles being decoupled from the power grid will be lower than the impact of the large number of replacement batteries that are coupled to the grid, thus increasing the stability of the maximum charging load.

The estimated minimum charging load curve 1004 shows the variation of the estimated minimum charging load of the batteries in the electric vehicle network over time. This curve shows two peak charging times, corresponding to a morning and an evening time window. These peak charging times may reflect typical charging demands associated with people commuting to and from respective work locations. The price of power curve 1008 illustrates the price of electricity over time, illustrating higher prices during peak demand hours of the day. As shown in FIG. 10A, the price of power curve 1008 has two peak pricing time windows, generally corresponding to morning and evening time windows.

The curves shown in FIG. 10A are merely illustrative: estimated minimum and maximum charging loads, as well as the price of power, may vary substantially from this illustration. For example, the estimated minimum charging load over time may be substantially different for weekends or holidays, where power demands from commuters are reduced. Further, the price of power curve 1008 may change from one day to the next, and may have more or fewer price levels than illustrated. One of skill in the art will also recognize that the estimated minimum charging load curve 1004 represents the rate of energy consumption over time, and does not directly represent the amount of energy required by the vehicles 102 of the electric vehicle network 100. However, as described above, the charging rate is calculated based on the minimum amount of additional energy required by the vehicles 102 of the electric vehicle network 100. Furthermore, the charging load curve 1004 could also be adapted to represent the minimum amount of additional energy required by the vehicles 102 at a given time. Likewise, the maximum charging load curve 1004 could be adapted to represent the maximum amount of energy that the batteries and storage components in the electric vehicle network 100 could hold at a given time.

The graph of FIG. 10A helps to illustrate how the above described information can be used to adjust the actual charging demand of the electric vehicle network 100 in order to optimize the price paid by the electric vehicle network for electricity. In particular, it can be seen that the minimum charging load 1004 has a first peak at a point between times t1 and t2. This peak charging load represents the charging load that will be placed on the system at that time in order for each vehicle to receive enough charge so that it can reach its final destination, which may be a work location. Also, the price of power curve 1008 shows that the price of power is at its highest level around the same time that the minimum charging load is at its morning peak. However, the price of power is at a minimum level between times t0 and t1, and it would be cheaper to purchase the electricity needed between times t1 and t2 when power is inexpensive, between times t0 and t1. The control center system 112 (or an operator of the control center system 112) can recognize this situation, and adjust battery charging policies to increase battery charging rates between times t0 and t1, even though the increased rates may result in vehicles receiving more energy than necessary to reach their intended destinations. In some instances, the actual charging rates of the batteries in the electric vehicle network may be increased to their maximum charging rates. Accordingly, the actual charging load of the electric vehicle network 100 during peak morning commute hours can be reduced, which in turn reduces the amount of expensive electricity that needs to be purchased during that time.

Of course, it may not be possible to charge the batteries of the electric vehicle network to completely satisfy the needs of the morning commute, as some vehicles may still require additional charge between times t1 and t2. Because the price of power is at its peak during this time window, the control center system 112 may keep the amount of charge provided to these vehicles to a minimum (e.g., only enough for that vehicle to reach its final destination) so as to reduce the amount of expensive electricity purchased by the electrical vehicle network. While the curves in FIG. 10A are discussed in terms of charging loads (e.g., rate of electrical energy consumption), users who are receiving additional charge during peak usage hours may not be willing to accept a lower charge rate, even if they are willing to accept only a minimum charge level. In other words, while a user may be willing to accept a 10 mile charge instead of a full battery charge, the user may wish to receive that 10 mile charge at the maximum charging rate. This preference may be accommodated, as the aggregate effect of vehicles receiving smaller charge levels is a reduced overall charging load, even if each individual battery is charged at a maximum rate.

A similar analysis may be made in response to the peak in the estimated minimum charging load curve 1006 seen during the evening (corresponding, for example, to the evening commute hours), between time t3 and time t4. In particular, because electricity is at its most expensive level during this time window, charging rates of the batteries in the electric vehicle network 100 may be increased during the preceding time window, between the time t2 and t3, when electricity is at a comparatively lower price. Similar to the scenario described above, those vehicles requiring additional charge between times t3 and t4 may only be given enough charge to meet that vehicle's minimum charge requirements (e.g., only enough for that vehicle to reach its final destination) in order to minimize the amount of expensive electricity purchased by the electrical vehicle network during the peak commute hours.

FIG. 10A also illustrates a time frame, after time t5, where the estimated minimum charging load is negative. A negative estimated minimum charging load simply indicates that the batteries (or other energy storage components) of the electric vehicle network 100 have more energy than needed to satisfy the minimum transportation requirements. This scenario is likely to occur later at night, when most drivers are home from work or their daily travels and are finished using their cars for the day. In some embodiments, the value of a negative estimated minimum charging load corresponds to a rate at which energy may be discharged from the batteries to the power grid, while still ensuring that the batteries have adequate charge levels to meet a user's transportation requirements. For instance, a vehicle that has 100 miles of charge at 10:00 PM may have an upcoming transportation need of 10 miles, in order to reach a user's work location, at 8:00 AM. Thus, the electric vehicle network 100 may discharge up to 90 miles worth of charge from that respective electric vehicle between 10:00 PM and 8:00 AM and still satisfy the vehicle's transportation requirements. By adjusting battery policies of the batteries in the electric vehicle network, including replacement batteries and/or additional energy storage components, it may be possible to store more energy than the electric vehicles require for a given time span. Often, the most convenient time to charge batteries beyond their minimum required levels is during the night, when most vehicles are not being used, and when electricity is typically at its cheapest. The stored energy may then be discharged back to the power grid when electricity is expensive. Such storage and discharge cycles may be implemented based on requests from utility providers, and/or to reduce electricity costs of the electric vehicle network 100. FIG. 10B illustrates a graph 1002 displaying estimated minimum and maximum charging load curves where the electric vehicle network is capable of discharging energy to the power grid, as described above.

As shown in FIG. 10B, the estimated minimum charging load curve 1010 is negative between times t0 and t2. As in FIG. 10A, time to may correspond to 6:00 AM. Thus, the overall amount of charge stored in the electric vehicle network may be very high, because most of the vehicles in the electric vehicle network were likely charging overnight when electricity was cheap. Furthermore, the replacement batteries 114 and/or additional energy storage components may likewise have been charging overnight. Accordingly, the control center system 112 may have allowed the batteries to charge completely (or at least more than necessary to satisfy upcoming transportation demands) in anticipation of the upcoming morning travel demands, and the upcoming increase in the price of electricity. The control center system 112 may then, at time t1, discharge energy from the batteries of the electric vehicle network 100 back to the power grid.

One of skill in the art will recognize that while the net charging rate of the electric vehicle network as described above and illustrated in FIG. 10B may be negative (indicating discharge to the power grid), individual vehicles may still receive energy from the power grid. For example, the replacement batteries 114 (and/or other storage components) may contain more energy than is required by the vehicles of the electric vehicle network 100 to reach their respective final destinations, even if an individual vehicle still requires additional energy. This may occur when a vehicle requires more than one battery's worth of charge to reach its final destination. However, because the replacement batteries 114 store more energy than that which is required by the vehicles, the replacement batteries 114 may be discharging to the grid while the vehicles are charging from the grid. The overall energy consumption by the electric vehicle network 100, therefore, may be negative. In effect, the process of storing and discharging energy as described above allows electric vehicles to use cheap energy, which was received and stored at periods of low demand, during periods of high demand and high electricity prices.

FIGS. 10A and 10B show predicted values (rather than current or instantaneous values) of the minimum and maximum charging loads over an exemplary time period. However, the actual maximum and minimum charging load curves will not be static over a given time window, but rather will change based on the adjustments to the actual charging load made by the control center system 112. In other words, when the control center system 112 determines that it is advantageous to increase the charging rate of the batteries in the electric vehicle network, the amount of energy stored in the electric vehicle network will increase. This increase in stored energy, in turn, will likely lower the future estimated minimum charging load, because the electric vehicle network may have acquired a quantity of energy over and above the vehicle's aggregated minimum energy requirements. Accordingly, the curves in FIGS. 10A and 10B may change as the battery policies are adjusted in real-time. In some embodiments, when curves or graphs are displayed to operators of the control center system 112, the curves are iteratively updated to account for the real-time battery policy adjustments.

In some embodiments, the total energy stored in the electric vehicle network 112 (e.g., in the batteries 104 of the vehicles 102, replacement batteries 114, storage batteries, etc.) is compared with the minimum energy requirements of the electric vehicle network 112, and battery policies are adjusted based on the results of the comparison. For example, in some embodiments, battery policies are adjusted so that the total energy stored in the electric vehicle network is always above the minimum energy requirements of the electric vehicle network 112. In some embodiments, the minimum energy requirements of the electric vehicle network 112 will be zero, such as when the electric vehicle network, in aggregate, requires no net additional energy from the power grid in order to allow each vehicle 102 to reach its final destination. Using the net additional energy is important, as it reflects the fact that some batteries (e.g., vehicle batteries 104 and replacement batteries 114) may be discharging power to the grid, while other batteries may be drawing power from the grid. Thus, a zero minimum energy requirement does not necessarily mean that every single vehicle in the electric vehicle network 112 has sufficient charge to reach its final destination.

The foregoing description, for purpose of explanation, has been described with reference to specific implementations. However, the illustrative discussions above are not intended to be exhaustive or to limit the disclosed ideas to the precise forms disclosed. Many modifications and variations are possible in view of the above teachings. The implementations were chosen and described in order to best explain the principles and practical applications of the disclosed ideas, to thereby enable others skilled in the art to best utilize them in various implementations with various modifications as are suited to the particular use contemplated.

Moreover, in the preceding description, numerous specific details are set forth to provide a thorough understanding of the presented ideas. However, it will be apparent to one of ordinary skill in the art that these ideas may be practiced without these particular details. In other instances, methods, procedures, components, and networks that are well known to those of ordinary skill in the art are not described in detail to avoid obscuring aspects of the ideas presented herein.

1. A method of managing an electric vehicle network, comprising:
receiving battery status data and vehicle location data from each of a plurality of electric vehicles;
utilizing the battery status data and the vehicle location data, and utilizing a final destination for each of the electric vehicles, and determining battery service data including a likely battery service station;
predicting demand at one or more battery service stations based at least on the battery service data determined for each of the electric vehicles; and
determining whether to adjust one or more battery policies responsive to the predicted demand.

2. The method of claim 1, wherein the battery service data includes a likely vehicle arrival time for the respective electric vehicle at the determined likely battery service station.

3. The method of claim 1, comprising:
estimating a minimum charging load at least partially based on an amount of additional energy required by the batteries of the electric vehicles to allow each of the electric vehicles to proceed to its respective final destination; and
estimating a maximum charging load that the batteries of the electric vehicles can place on a power grid,
said predicting of the demand utilizing the estimated minimum charging load and the estimated maximum charging load.

4. The method of claim 3 wherein the estimating of minimum charging load comprises one of the following: (i) the minimum charging load is estimated at least partially based on actual energy demand of the electric vehicle network determined over a predetermined time window based at least partially on data received from the vehicles; (ii) the estimated minimum charging load is determined as a sum of estimated minimum individual charging loads placed on the power grid by each respective electric vehicle.

5. (canceled)

6. The method of claim 3, wherein the estimated maximum charging load is at least partially based on an estimated load placed on the power grid if all of the vehicles coupled to the power grid at a certain time were to be simultaneously charged at a maximum rate.

7. The method of claim 1, wherein the determining of whether to adjust one or more battery policies includes:
determining a supply of battery services at the one or more battery service stations; and
comparing the predicted demand at the one or more battery service stations and the supply of battery services at the one or more battery service stations.

8. The method of claim 1, further comprising adjusting the one or more battery policies, said adjusting comprising one of the following:
(a) adjusting the one or more battery policies based on the demand predicted at the one or more battery service stations;
(b) utilizing the demand predicted at the one or more battery service stations for adjusting the one or more battery policies, and increasing or decreasing a charge rate of: at least one replacement battery coupled to the electric vehicle network at a battery service station; or of a battery of at least one of the electric vehicles coupled to the electric vehicle network at a battery service station;
(c) utilizing the demand predicted at the one or more battery service stations for adjusting the one or more battery policies, and recommending an alternate battery service station to a user of a respective electric vehicle;
(d) utilizing the demand predicted at the one or more battery service stations for adjusting the one or more battery policies, and changing a number of available replacement batteries at one or more of the battery service stations;
(e) determining a supply of battery services at the one or more batter service stations, adjusting the one or more battery policies based on a comparison between the predicted demand at the one or more battery service stations and the supply of battery services at the one or more battery service stations.

9. (canceled)

10. The method of claim 1, wherein the determining of the final destination comprises carrying out at least one of the following: (1) receiving respective final destinations from at least a subset of the plurality of electric vehicles; (2) predicting the final destination of a respective electric vehicle when an operator of the respective electric vehicle has not selected an intended final destination.

11. The method of claim 1, wherein the determining of the final destination comprises receiving respective final destinations from at least a subset of the plurality of electric vehicles, the respective final destinations being intended destinations selected by respective users of the subset of electric vehicles.

12. The method of claim 1, wherein the determining of the final destination comprises predicting the final destination of a respective electric vehicle when an operator of the respective electric vehicle has not selected an intended final destination, the predicted final destination being selected from a group consisting of: a home location; a work location: a battery service station; a previously visited location; and a frequently visited location.

13. (canceled)

14. The method of claim 1, wherein the one or more battery service stations are selected from of the following: charge stations for recharging the batteries of the electric vehicles; and battery exchange stations for replacing the batteries of the electric vehicles.

15. The method of claim 1, wherein the demand is predicted for a predetermined time or for a predetermined range of time.

16. (canceled)

17. (canceled)

18. (canceled)

19. The method of claim 1, further comprising at least one of the following;
informing a utility provider of an expected power demand, the expected power demand based at least partially on the predicted demand at the one or more battery service stations; and
increasing the demand predicted at the one or more battery service stations to account for demand from one or more electric vehicles of a second plurality of electric vehicles.

20. The method of claim 1, wherein determining a respective likely battery service station and a respective likely vehicle arrival time for a respective electric vehicle is further based on a speed of the respective electric vehicle.

21. The method of claim 1, further comprising increasing the demand predicted at the one or more battery service stations to account for demand from one or more electric vehicles of a second plurality of electric vehicles, the second plurality of vehicles including vehicles that are not in communication with the computer system.

22. (canceled)

23. The method of claim 1, further comprising:
displaying, on a display device, a map illustrating a geographic area having a plurality of battery service stations; and
displaying on the map one or more graphical representations indicating a respective demand for one or more of the battery service stations in the illustrated geographic area.

24. A system for managing an electric vehicle network, comprising:
at least one communication module for exchanging data with one or more battery service stations and with a plurality of electric vehicles;
one or more processors; and
memory for storing data and one or more programs for execution by the one or more processors, comprising:
a battery status module configured to determine a battery charge status based on battery status data received from each of the plurality of electric vehicles;
a vehicle location database for maintaining location data received from the vehicles; and
a demand prediction module configured and operable to identify a final destination for each of the electric vehicles, determine for each respective electric vehicle a location of a likely battery service station based at least partially on the location, the final destination, and the battery charge status for that electric vehicle, and predict demand at one or more battery service stations based at least partially on the likely battery service location for each respective electric vehicle.

25. The system of claim 24, comprising at least one of the following:
a battery service station module configured and operable to receive and maintain station status data received from the battery service stations;
a battery policy module configured and operable to determine whether to adjust one or more battery policies based at least on one of the predicted demand and the station status data; and
a map module configured and operable to generate a graphical representation indicating a respective demand for battery services in one or more geographic areas.

26. (canceled)

27. (canceled)

28. A method of managing an electric vehicle network comp sin a plurality of electric vehicles each having one or more batteries, the method comprising:
estimating a minimum charging load at least partially based on an amount of additional energy required by the batteries of the electric vehicles to allow each of the electric vehicles to proceed to its respective final destination;
estimating a maximum charging load that the batteries of the electric vehicles can place on a power grid; and
adjusting one or more battery policies of the batteries of the electric vehicles to adjust an actual charging load of the electric vehicle network between the estimated minimum charging load and the estimated maximum charging load based on certain predetermined factors.

29. The method of claim 28, wherein the estimating of the minimum charging load comprises at least one of the following:
(i) estimating of the minimum charging load as at least partially based on measured actual energy demand of the electric vehicle network over a predetermined time window;
(ii) determining the estimated minimum charging load as a sum of estimated minimum individual charging loads placed on the power grid by each respective electric vehicle;
(iii) determining the estimated minimum charging load as at least partially based on the final destination, a current location, and a battery charge level of each respective electric vehicle.

30. (canceled)

31. (canceled)

32. The method of claim 28, wherein the determination of the estimated maximum charging load comprises at least one of the following: (a) the estimated maximum charging load is at least partially based on an estimated load placed on the power grid of all of a predicted number of vehicles coupled to the power grid at a certain time were to be simultaneously charged at a maximum rate; and (b) the estimated maximum charging load is at least based on an estimated load laced on the power grid if all of the vehicles coupled to the power grid at a certain time were to be simultaneously charged at a maximum rate.

33. (canceled)

34. The method of claim 28, wherein the one or more battery policies are adjusted at least partially based on a price of energy from the power grid.

35. The method according to claim 28, wherein the batteries of the electric vehicles each have an existing charge level, and wherein the amount of additional energy required by the batteries of the electric vehicles is an amount of energy in addition to an aggregation of the existing charge level of each of the electric vehicles.

36. The method according to claim 28, wherein each respective electric vehicle has an associated minimum battery charge level that is determined by one or more service agreements with an owner or an operator of the respective vehicle.

37. The method of claim 28, further comprising:
sending, to a utility provider, the estimated minimum charging load and the estimated maximum charging load; and
receiving from the utility provider an energy plan comprising preferred charging loads for a predetermined time window;
wherein the one or more battery policies are adjusted in accordance with the energy plan.

38. The method according to claim 28, wherein when the batteries of a respective electric vehicle contain more energy than necessary for the respective electric vehicle to reach its final destination, the battery of the respective electric vehicle being capable of providing energy to the power grid.

39. The method of claim 28, wherein adjusting the one or more charging policies comprises increasing or decreasing a charge rate of at least one of: at least one of the replacement batteries coupled to the power grid; and at least one electric vehicle coupled to the power grid.

40. The method of claim 39, wherein the charge rate is negative.

41. The method of claim 28, wherein the electric vehicle network includes one or more storage batteries coupled to the power grid, and wherein adjusting the one or more battery policies comprises increasing or decreasing a charge rate of at least one of the storage batteries.

42. The method of claim 28, wherein the estimated minimum charging load and the estimated maximum charging load are represented by a set of data points representing energy quantities over a predefined time.

43. The method of claim 42, further comprising:
fitting at least a subset of the set of data points to a curve function; or
displaying, on a display device, a graph containing at least a subset of the set of data points.

44. The method of claim 28, wherein the one or more battery policies are adjusted in order to minimize energy costs of the electric vehicle network over a predetermined time window.
